(19) United States
(12) Patent Application Publication
(10) Pub. No.: US 2026/0204310 A1
(43) Pub. Date: Jul. 16, 2026

(54) SEMICONDUCTOR MEMORY DEVICE

(71) Applicant: Samsung Electronics Co., Ltd., Suwon-si (KR)

(72) Inventors: Myeongsik RYU, Suwon-si (KR); Seokjae LEE, Suwon-si (KR); Kyoungmin KIM, Suwon-si (KR); Donggeon KIM, Suwon-si (KR); Sangwook PARK, Suwon-si (KR); Inseok BAEK, Suwon-si (KR); Bok-Yeon WON, Suwon-si (KR); Jongmoon YOON, Suwon-si (KR)

(21) Appl. No.: 19/135,752

(22) PCT Filed: Dec. 6, 2022
(86) PCT No.: PCT/KR2022/019724

§ 371 Date: Jun. 4, 2025

(51) Int. Cl. G11C 11/408; G11C 5/06

(52) U.S. Cl. CPC G11C 11/4085; G11C 5/063

(57) ABSTRACT

A semiconductor memory device according to an embodiment of the present disclosure includes a first sub-word line driver and a second sub-word line driver. The first sub-word line driver includes a first pull-down transistor and a first keeping transistor. The second sub-word line driver includes a second pull-down transistor and a second keeping transistor. A source region of the first pull-down transistor and a source region of the second keeping transistor are disposed to share a first doping region on a semiconductor substrate, and a source region of the second pull-down transistor and a source region of the first keeping transistor are disposed to share a second doping region on the semiconductor substrate.

### TECHNICAL FIELD

The present disclosure relates to a semiconductor device, and more particularly, relates to a semiconductor memory device.

### BACKGROUND ART

A semiconductor memory device may be classified as a volatile semiconductor memory device or a nonvolatile semiconductor memory device. In a volatile memory device such as dynamic random access memory (DRAM) in which data are stored by charging/discharging a cell capacitor, the stored data are retained while a power is applied, but the stored data are lost when a power is not applied.

As the capacity of the DRAM increases, the number of memory cells connected to one word line increases, and the space between word lines decreases. To drive the word lines, a method of dividing the word lines into a plurality of sub-word lines and driving each sub-word line by using a sub-word line driver is used. To improve the degree of integration of the DRAM, a method of reducing the area occupied by the sub-word line driver is required.

### DETAILED DESCRIPTION OF THE INVENTION

### Techinical Problem

An object of the present disclosure is directed to provide a semiconductor memory device which reduces the chip size by reducing the area on a semiconductor substrate occupied by a sub-word line driver.

An object of the present disclosure is directed to provide a semiconductor memory device which allows various patterns included in a sub-word line driver to be elaborately formed by adjusting placements of transistors included in the sub-word line driver.

### Technical Solution

A semiconductor memory device according to an embodiment of the present disclosure for achieving the objects includes a first sub-word line driver and a second sub-word line driver. The first sub-word line driver includes a first pull-down transistor and a first keeping transistor. The first pull-down transistor pulls down a first word line in a deactivation interval of the first word line. The first keeping transistor maintains a voltage level of the pulled-down first word line in the deactivation interval of the first word line. The second sub-word line driver includes a second pull-down transistor and a second keeping transistor. The second pull-down transistor pulls down a second word line in a deactivation interval of the second word line. The second keeping transistor maintains a voltage level of the pulled-down second word line in the deactivation interval of the second word line. A source region of the first pull-down transistor and a source region of the second keeping transistor are disposed to share a first doping region on a semiconductor substrate, and a source region of the second pull-down transistor and a source region of the first keeping transistor are disposed to share a second doping region on the semiconductor substrate.

A semiconductor memory device according to an embodiment of the present disclosure for achieving the above object includes a memory cell array and first to fourth sub-word line drivers. The memory cell array includes a plurality of memory cells connected to a plurality of word lines. The first to fourth sub-word line drivers respectively activate a first word line to a fourth word line, which extend to one side of the memory cell array and are adjacent to each other, from among the plurality of word lines. The first sub-word line driver includes a first pull-down transistor and a first keeping transistor. The first pull-down transistor pulls down the first word line, in a deactivation interval of the first word line. The first keeping transistor maintains a voltage level of the pulled-down first word line, in the deactivation interval of the first word line. The second sub-word line driver includes a second pull-down transistor and a second keeping transistor. The second pull-down transistor pulls down the second word line, in a deactivation interval of the second word line. The second keeping transistor maintains a voltage level of the pulled-down second word line, in the deactivation interval of the second word line. A source region of the first pull-down transistor and a source region of the second keeping transistor are disposed to share a first doping region on a semiconductor substrate, and a source region of the second pull-down transistor and a source region of the first keeping transistor are disposed to share a second doping region on the semiconductor substrate.

A semiconductor memory device according to an embodiment of the present disclosure for achieving the above object includes a first sub-word line driver, a second sub-word line driver, a first metal line, a second metal line, and a third metal line. The first sub-word line driver includes a first pull-down transistor and a first keeping transistor. The first pull-down transistor pulls down a first word line, in a deactivation interval of the first word line. The first keeping transistor maintains a voltage level of the pulled-down first word line, in the deactivation interval of the first word line. The second sub-word line driver includes a second pull-down transistor and a second keeping transistor. The second pull-down transistor pulls down a second word line, in a deactivation interval of the second word line. The second keeping transistor maintains a voltage level of the pulled-down second word line, in the deactivation interval of the second word line. The first metal line is electrically connected to gates of the first and second pull-down transistors. The second metal line is electrically connected to a gate of the first keeping transistor. The third metal line is electrically connected to a gate of the second keeping transistor. A source region of the first pull-down transistor and a source region of the second keeping transistor are disposed to share a first doping region on a semiconductor substrate, and a source region of the second pull-down transistor and a source region of the first keeping transistor are disposed to share a second doping region on the semiconductor substrate. A drain region of the first keeping transistor and a drain region of the first pull-down transistor are disposed to share a third doping region on the semiconductor substrate, and a drain region of the second keeping transistor and a drain region of the second pull-down transistor are disposed to share a fourth doping region on the semiconductor substrate.

### Advantageous Effects of the Invention

A semiconductor memory device according to an embodiment of the present disclosure may reduce the chip size by reducing the area on a semiconductor substrate occupied by a sub-word line driver.

The semiconductor memory device according to an embodiment of the present disclosure may allow various patterns included in the sub-word line driver to be elaborately formed by adjusting placements of transistors included in the sub-word line driver.

### BRIEF DESCRIPTION OF THE DRAWINGS

FIGS. 1 and 2 are block diagrams illustrating a semiconductor memory device including sub-word line drivers according to an embodiment of the present disclosure.

FIG. 3 is a circuit diagram illustrating some of sub-word line drivers illustrated in FIGS. 1 and 2.

FIG. 4 is a timing diagram for describing an operation of sub-word line drivers of FIG. 1.

FIGS. 5 and 6 are diagrams for describing embodiments of the placement of transistors included in sub-word line drivers of FIG. 3.

FIGS. 7 and 8 are diagrams for describing an embodiment of the placement of doping regions or metal lines included in sub-word line drivers of FIG. 1.

FIGS. 9 and 10 are diagrams for describing an embodiment of the placement of transistors, doping regions, or metal lines included in sub-word line drivers of FIG. 1.

FIG. 11 is a diagram for describing the placement of sub-word line drivers of FIG. 1.

FIG. 12 is a diagram for describing an embodiment of the placement of transistors, doping regions, or metal lines included in sub-word line drivers according to an embodiment of the present disclosure.

FIG. 13 is a diagram for describing the placement of sub-word line drivers of FIG. 12.

FIG. 14 is a diagram illustrating an embodiment of the placement of sub-word line drivers according to an embodiment of the present disclosure.

FIG. 15 is a block diagram illustrating a semiconductor memory device including sub-word line drivers according to an embodiment of the present disclosure.

FIG. 16 is a flowchart illustrating a semiconductor memory device designing and manufacturing method according to an embodiment of the present disclosure.

FIGS. 17a, 17b, and 17c are diagrams for describing photo masks for forming patterns included in sub-word line drivers of FIG. 12.

FIG. 18 is a block diagram illustrating a computing system including sub-word line drivers according to an embodiment of the present disclosure.

FIG. 19 is a diagram illustrating a data center to which a semiconductor memory device including sub-word line drivers according to an embodiment of the present disclosure is applied.

### BEST MODE FOR CARRYING OUT THE INVENTION

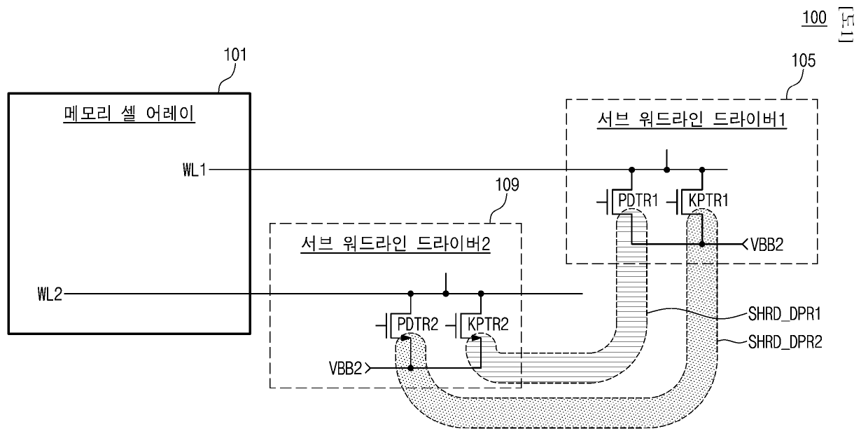

A drawing indicating the best mode for carrying out the present disclosure is FIG. 1.

### Mode for Carrying Out the Invention

Below, embodiments of the present disclosure will be described in detail and clearly to such an extent that one skilled in the art easily carries out the present disclosure.

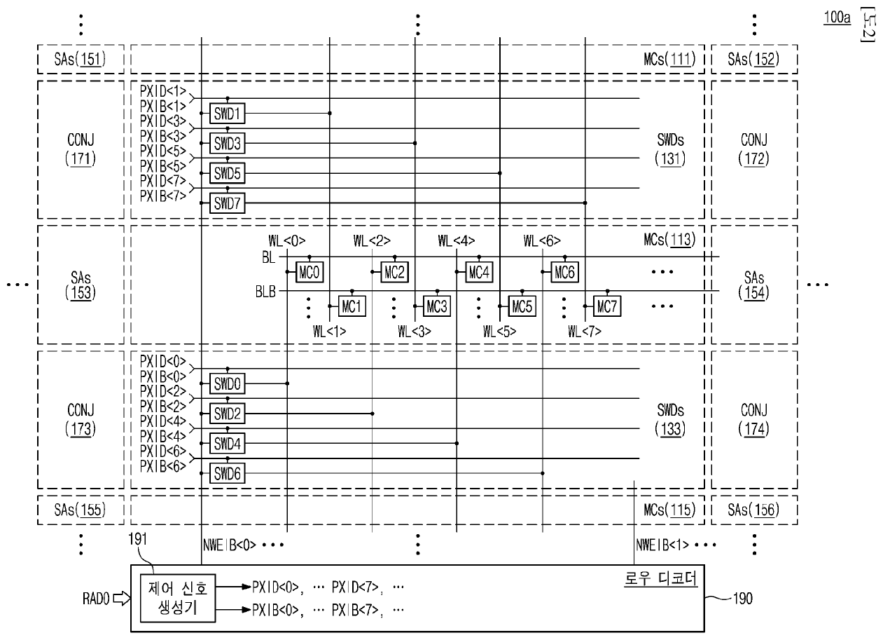

FIGS. 1 and 2 are block diagrams illustrating a semiconductor memory device including sub-word line drivers according to an embodiment of the present disclosure.

Referring to FIG. 1, a semiconductor memory device 100 may be a volatile memory device. Below, it is assumed that the volatile memory device is a dynamic random access memory (DRAM), but this is provided only as an example. In an embodiment, the semiconductor memory device 100 may be an arbitrary semiconductor memory device identical or similar in structure to the DRAM.

The semiconductor memory device 100 may include a memory cell array 101 and a plurality of sub-word line drivers, and the memory cell array 101 may include a plurality of memory cells connected to a plurality of word lines and a plurality of bit lines and disposed at rows and columns. The plurality of sub-word line drivers may activate the plurality of word lines, respectively.

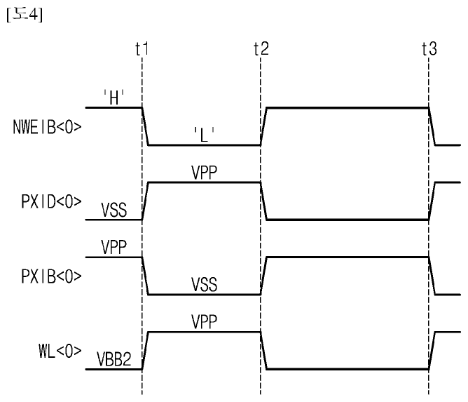

In an embodiment, an activation interval and a deactivation interval may be defined for each of the plurality of word lines. The activation interval may be an interval in which each of the plurality of word lines maintains a first voltage level to drive selected memory cells in operation modes (e.g., a write operation mode, a read operation mode, and a self-refresh operation mode) of the semiconductor memory device 100. The deactivation interval may be an interval in which each of the plurality of word lines maintains a second voltage level lower than the first voltage level not to drive unselected memory cells in each of the operation modes of the semiconductor memory device 100. The activation interval and the deactivation interval may be a specific time interval and may be respectively referred to as a “driving time interval” and a “non-driving time interval”. The activation interval and the deactivation interval will be described with reference to FIG. 4.

The plurality of sub-word line drivers may include a first sub-word line driver 105 and a second sub-word line driver 109. The first and second sub-word line drivers 105 and 109 may respectively activate first and second word lines WL1 and WL2 among the plurality of word lines and may drive corresponding memory cells (or memory cell rows) among the plurality of memory cells.

The first sub-word line driver 105 may include a first pull-down transistor PDTR1 and a first keeping transistor KPTR1, and the second sub-word line driver 109 may include a second pull-down transistor PDTR2 and a second keeping transistor KPTR2. Although not illustrated in FIG. 1, each of the first sub-word line driver 105 and the second sub-word line driver 109 may further include a pull-up transistor for pulling up the corresponding word line and may further include one or more other transistors.

The first pull-down transistor PDTR1 may pull down the first word line WL1 in the disable interval of the first word line WL1, and the first keeping transistor KPTR1 may maintain the voltage level of the first word line WL1 thus pulled down. For example, in the disable interval of the first word line WL1, the first pull-down transistor PDTR1 may be turned on such that the first word line WL1 is pulled down to a negative voltage VBB2 corresponding to the second voltage level, and the first keeping transistor KPTR1 may be turned on such that the voltage level of the first word line WL1 thus pulled down is maintained at the negative voltage VBB2.

The second pull-down transistor PDTR2 may pull down the second word line WL2 in the disable interval of the second word line WL2, and the second keeping transistor KPTR2 may maintain the voltage level of the second word line WL2 thus pulled down. For example, in the disable interval of the second word line WL2, the second pull-down transistor PDTR2 may be turned on such that the second word line WL2 is pulled down to the negative voltage VBB2 corresponding to the second voltage level, and the second keeping transistor KPTR2 may be turned on such that the voltage level of the second word line WL2 thus pulled down is maintained at the negative voltage VBB2.

Each of the first pull-down transistor PDTR1, the first keeping transistor KPTR1, the second pull-down transistor PDTR2, and the second keeping transistor KPTR2 may include a drain region and a source region and may include a channel region which is formed between the drain region and the source region at a time point at which each transistor is turned on. The drain region may be referred to as a “drain active region”, and the source region may be referred to as a “source active region”. Direct contacts for the electrical connection with external circuits may be disposed on the drain region and the source region.

In an embodiment, the first pull-down transistor PDTR1, the first keeping transistor KPTR1, the second pull-down transistor PDTR2, and the second keeping transistor KPTR2 may be formed on a semiconductor substrate.

The source regions of the first pull-down transistor PDTR1 and the second keeping transistor KPTR2 may be disposed on the semiconductor substrate so as to share a doping region SHRD_DPR1 on the semiconductor substrate. For example, the source regions of the first pull-down transistor PDTR1 and the second keeping transistor KPTR2 may be formed on the doping region SHRD_DPR1 on the semiconductor substrate. For example, the doping region SHRD_DPR1 on the semiconductor substrate may include the source regions of the first pull-down transistor PDTR1 and the second keeping transistor KPTR2.

The source regions of the second pull-down transistor PDTR2 and the first keeping transistor KPTR1 may be disposed on the semiconductor substrate so as to share a doping region SHRD_DPR2 on the semiconductor substrate. For example, the source regions of the second pull-down transistor PDTR2 and the first keeping transistor KPTR1 may be formed on the doping region SHRD_DPR2 on the semiconductor substrate. For example, the doping region SHRD_DPR2 on the semiconductor substrate may include the source regions of the second pull-down transistor PDTR2 and the first keeping transistor KPTR1.

Although not illustrated in FIG. 1, the drain regions of the first pull-down transistor PDTR1 and the first keeping transistor KPTR1 may be disposed on the semiconductor substrate so as to share another doping region different from the doping regions SHRD_DPR1 and SHRD_DPR2. The drain regions of the second pull-down transistor PDTR2 and the second keeping transistor KPTR2 may be disposed on the semiconductor substrate so as to share another doping region different from the doping regions SHRD_DPR1 and SHRD_DPR2.

Referring to FIG. 2, a semiconductor memory device 100a may include memory cells (or “memory cell array”) 111, 113, and 115, sub-word line drivers 131 and 133, sense amplifier blocks 151, 152, 153, 154, 155, and 156, conjunction circuits 171, 172, 173, and 174, and a row decoder 190. The row decoder 190 may include a control signal generator 191.

The row decoder 190 may receive a row address RADO and may generate signals for driving selected memory cells among the memory cells 111, 113, and 115. For example, based on the row address RADO, the row decoder 190 may generate one or more of word line enable signals NWEIB<0>, NWEIB<1>, etc. and one or more of sub-word line driver control signals PXID<0>, . . . , PXID<7>. . . , PXIB<0>, . . . , PXIB<7>, etc. and may drive the selected memory cells.

In an embodiment, the row decoder 190 may generate one or more of the word line enable signals NWEIB<0>, NWEIB<1>, etc. based on first bits of the row address RADO, and the control signal generator 191 included in the row decoder 190 may generate one or more of the sub-word line driver control signals PXID<0>, . . . , PXID<7>. . . , PXIB<0>, . . . , PXIB<7>, etc. based on second bits of the row address RADO. For example, when a result of decoding the first bits and the second bits of the row address RADO indicates the case of driving one or more of memory cells MC0, MC1, MC2, MC3, MC4, MC5, MC6, and MC7, the row decoder 190 may generate the word line enable signal NWEIB<0>. In the case of driving one or more (e.g., MC0, MC2, MC4, and MC6) of the memory cells, the control signal generator 191 may generate one or more (e.g., PXID<0>, PXIB<0>, PXID<2>, PXIB<2>, PXID<4>, PXIB<4>, PXID<6>, and PXIB<6>) of the sub-word line driver control signals PXID<0>, . . . , PXID<7>. . . , PXIB<0>, . . . , PXIB<7>, etc. In this case, sub-word line drivers SWD0, SWD2, SWD4, and SWD6 may activate word lines WL<0>, WL<2>, WL<4>, and WL<6>based on the word line enable signal NWEIB<0>and the sub-word line driver control signals PXID<0>, PXIB<0>, PXID<2>, PXIB<2>, PXID<4>, PXIB<4>, PXID<6>, and PXIB<6>.

The conjunction circuits 171 to 174 may include metal lines for supplying a power to the sense amplifier blocks 151 to 156, the sub-word line drivers 131 and 133, and the memory cells 111, 113, and 115 or providing electrical signals generated therefrom, and may include various circuits for any other operations of the semiconductor memory device 100a.

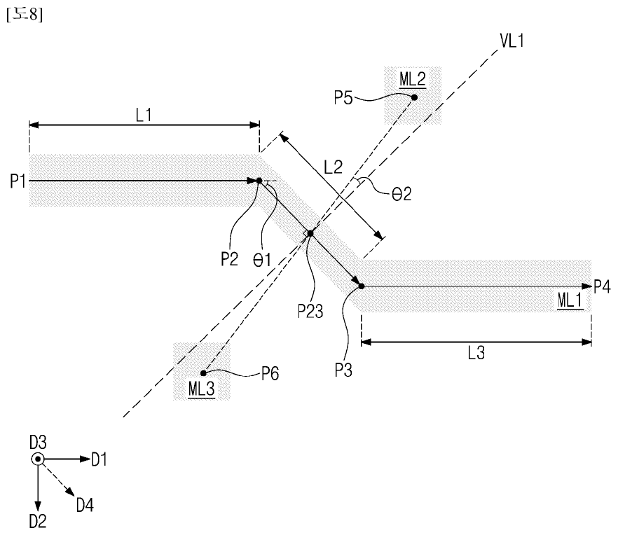

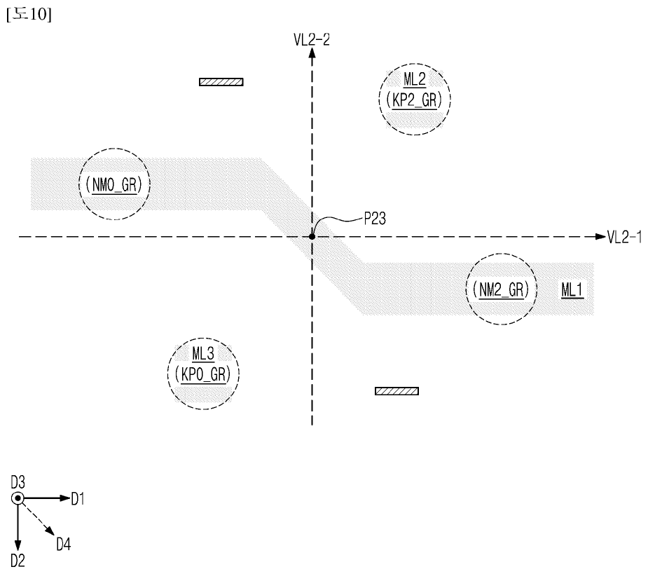

Each of the sub-word line drivers SWD0, SWD1, SWD2, SWD3, SWD4, SWD5, SWD6, and SWD7 may include a pull-down transistor and a keeping transistor. A source region of a pull-down transistor included in one sub-word line driver and a source region of a keeping transistor included in another sub-word line driver may share one doping region on a semiconductor substrate. Drain regions of a pull-down transistor and a keeping transistor included in one sub-word line driver may share another doping region on the semiconductor substrate. The shared doping regions may be disposed on the semiconductor substrate to be spaced apart from each other, and some of the shared doping regions may be disposed to be symmetrical. The shared doping regions will be described with reference to FIGS. 7 and 9.

According to the above configuration, a semiconductor memory device according to an embodiment of the present disclosure may reduce the area on the semiconductor substrate occupied by the sub-word line driver, and thus, the chip size may be reduced. Also, various patterns included in the sub-word line driver may be elaborately formed by adjusting placements of transistors included in the sub-word line driver.

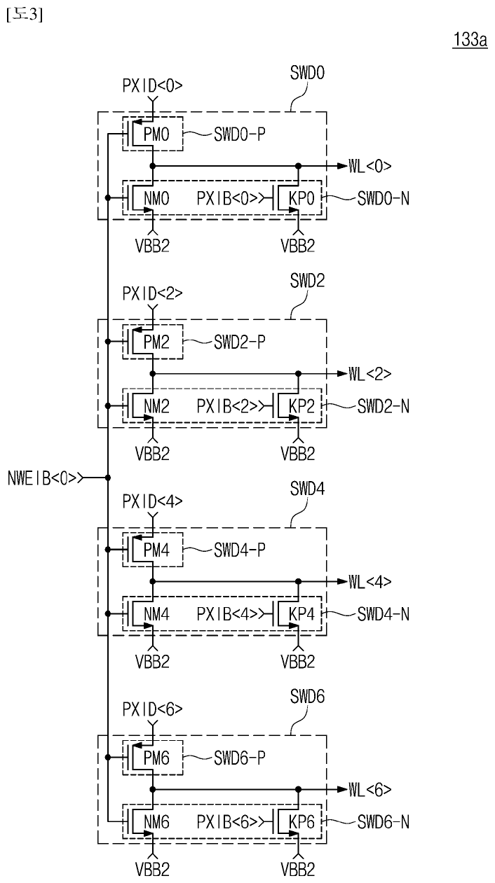

FIG. 3 is a circuit diagram illustrating some of sub-word line drivers illustrated in FIGS. 1 and 2.

In FIGS. 1 to 3, components having the same reference numerals/signs may perform substantially the same functions. Referring to FIG. 3, some 133a of sub-word line drivers may include sub-word line drivers SWD0, SWD2, SWD4, and SWD6, and each of the sub-word line drivers SWD0, SWD2, SWD4, and SWD6 may include a pull-up transistor, a pull-down transistor, and a keeping transistor. The pull-up transistor may be formed of a MOS transistors of a first conductivity, each of the pull-down transistor and the keeping transistor may be formed of a MOS transistor of a second conductivity.

For example, the sub-word line driver SWD0 may include a pull-up transistor PM0 formed of a PMOS transistor SWD0-P, and a pull-down transistor NM0 and a keeping transistor KP0 each formed of an NMOS transistor SWD0-N. Accordingly, the PMOS transistor SWD0-P of the sub-word line driver SWD0 may refer to the pull-up transistor PM0, and the NMOS transistor SWD0-N of the sub-word line driver SWD0 may refer to the pull-down transistor NM0 and the keeping transistor KP0.

The Pull-up transistor PM0 included in the sub-word line driver SWD0 may be connected between a terminal to which the sub-word line driver control signal PXID<0>is applied and the corresponding word line (e.g., WL<0>), and the pull-down transistor NM0 and the keeping transistor KP0 included in the sub-word line driver SWD0 may be connected in parallel between the corresponding word line and terminals to which the negative voltage VBB2 is applied. For example, the sub-word line driver control signal PXID<0>may be applied to the source region of the pull-up transistor PM0, and the negative voltage VBB2 may be applied to the source region of each of the pull-down transistor NM0 and the keeping transistor KP0. The drain region of each of the pull-up transistor PM0, the pull-down transistor NM0, and the keeping transistor KP0 may be connected to the corresponding word line.

The remaining sub-word line drivers SWD2, SWD4, and SWD6 may also be implemented to be identical or similar to the sub-word line driver SWD0.

In an embodiment, the sub-word line driver SWD2 may include a pull-up transistor PM2 formed of a PMOS transistor SWD2-P, and a pull-down transistor NM2 and a keeping transistor KP2 each formed of an NMOS transistor SWD2-N, and the sub-word line driver control signal PXID<2>and the negative voltage VBB2 may be applied to the sub-word line driver SWD2. The sub-word line driver SWD4 may include a pull-up transistor PM4 formed of a PMOS transistor SWD4-P, and a pull-down transistor NM4 and a keeping transistor KP4 each formed of an NMOS transistor SWD4-N, and the sub-word line driver control signal PXID<4>and the negative voltage VBB2 may be applied to the sub-word line driver SWD4. The sub-word line driver SWD6 may include a pull-up transistor PM6 formed of a PMOS transistor SWD6-P, and a pull-down transistor NM6 and a keeping transistor KP6 each formed of an NMOS transistor SWD6-N, and the sub-word line driver control signal PXID<6>and the negative voltage VBB2 may be applied to the sub-word line driver SWD6.

In this case, each of the pull-up transistors PM0, PM2, PM4, and PM6 and the pull-down transistors NM0, NM2, NM4, and NM6 included in the sub-word line drivers SWD0, SWD2, SWD4, and SWD6 may include a gate terminal configured to receive the word line enable signal NWEIB<0>. Each of the keeping transistors KP0, KP2, KP4, and KP6 included in the sub-word line drivers SWD0, SWD2, SWD4, and SWD6 may include a gate terminal configured to receive a corresponding control signal among the sub-word line driver control signals PXIB<0>, PXIB<2>, PXIB<4>, and PXIB<6>. Sub-word line driver control signals respectively applied to the keeping transistors KP0, KP2, KP4, and KP6 may be referred to as a “keeping control signal”.

The sub-word line drivers SWD0, SWD2, SWD4, and SWD6 may respectively activate the word lines WL<0>, WL<2>, WL<4>, and WL<6>.

In an embodiment, the word lines WL<0>, WL<2>, WL<4>, and WL<6>may respectively correspond to the sub-word line drivers SWD0, SWD2, SWD4, and SWD6. In an embodiment, the word lines WL<0>, WL<2>, WL<4>, and WL<6>may be word lines which extend to one side of the memory cell array and are adjacent to each other.

FIG. 4 is a timing diagram for describing an operation of sub-word line drivers of FIG. 1. Only components associated with the sub-word line driver SWD0 among the sub-word line drivers SWD0, SWD2, SWD4, and SWD6 illustrated in FIGS. 2 and 3 will be described, but this is provided only as an example. The remaining sub-word line drivers may also operate to be substantially the same as the sub-word line driver SWD0. In FIG. 4, signal levels of the word line enable signal NWEIB<0>and the sub-word line driver control signals PXID<0>and PXIB<0>applied to the sub-word line driver SWD0 as time points t1, t2, and t3 pass are illustrated, and a voltage level of the word line WL<0>which the sub-word line driver SWD0 activates is illustrated.

Referring to FIGS. 3 and 4, the word line enable signal NWEIB<0>may have one of a high level (H) and a low level (L), and the sub-word line driver control signals PXID<0>and PXIB<0>may have one of a voltage level VSS and a voltage level VPP. The high level may be a signal level sufficient to turn off the pull-up transistor PM0 and to turn on the pull-down transistor NM0, and the low level may be a signal level sufficient to turn on the pull-up transistor PM0 and to turn off the pull-down transistor NM0. The voltage level VPP may be a high voltage level sufficient to activate the word line WL<0>, and the voltage level VSS may be a low voltage level sufficient to deactivate the word line WL<0>.

The word line enable signal NWEIB<0>may have the high level before t1, may transition to the low level at t1, and may maintain the low level until t2. Also, the word line enable signal NWEIB<0>may transition to the high level at t2 and may maintain the high level until t3.

The sub-word line driver control signal PXID<0>may have the voltage level VSS before t1, may transition to the voltage level VPP at t1, and may maintain the voltage level VPP until t2. Also, the sub-word line driver control signal PXID<0>may transition to the voltage level VSS at t2 and may maintain the voltage level VSS at t3. When the sub-word line driver control signal PXID<0>has the voltage level VSS, the sub-word line driver control signal PXIB<0>may have the voltage level VPP; when the sub-word line driver control signal PXID<0>has the voltage level VPP, the sub-word line driver control signal PXIB<0>may have the voltage level VSS.

Before t1 or between t2 and t3, because the word line enable signal NWEIB<0>has the high level and the sub-word line driver control signal PXIB<0>has the voltage level VPP, the pull-down transistor NM0 and the keeping transistor KP0 may be turned on, and the voltage level of the word line WL<0>may indicate the negative voltage VBB2.

Between t1 and t2 or after t3, because the word line enable signal NWEIB<0>has the low level and the sub-word line driver control signal PXIB<0>has the voltage level VSS, the pull-up transistor PM0 may be turned on, and the voltage level of the word line WL<0>may indicate the voltage level VPP being the voltage level of the sub-word line driver control signal PXID<0>.

Between t1 and t2, the word line WL<0>may be activated. Before t1 or between t2 and t3, the word line WL<0>may be deactivated.

As described with reference to FIG. 1, the activation interval and the deactivation interval of the word line WL<0>may be defined. The time interval from t1 to t2 may correspond to the activation interval of the word line WL<0>, and the time interval from t2 to t3 may correspond to the deactivation interval of the word line WL<0>.

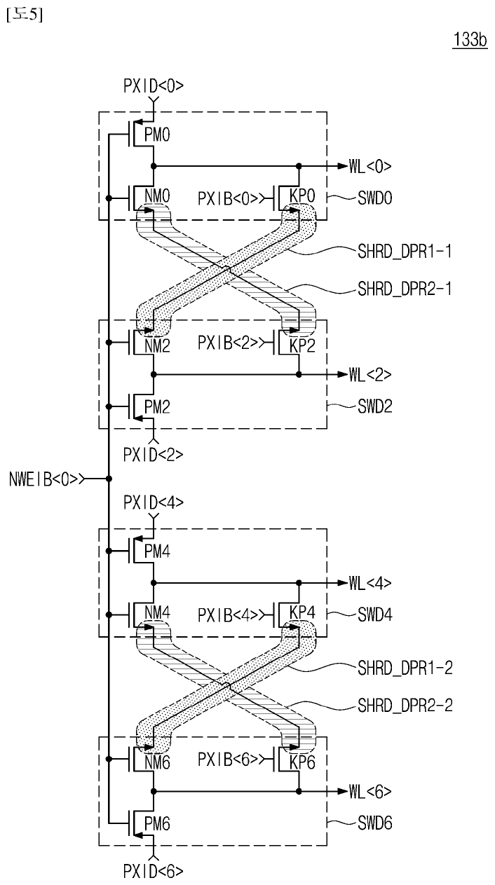

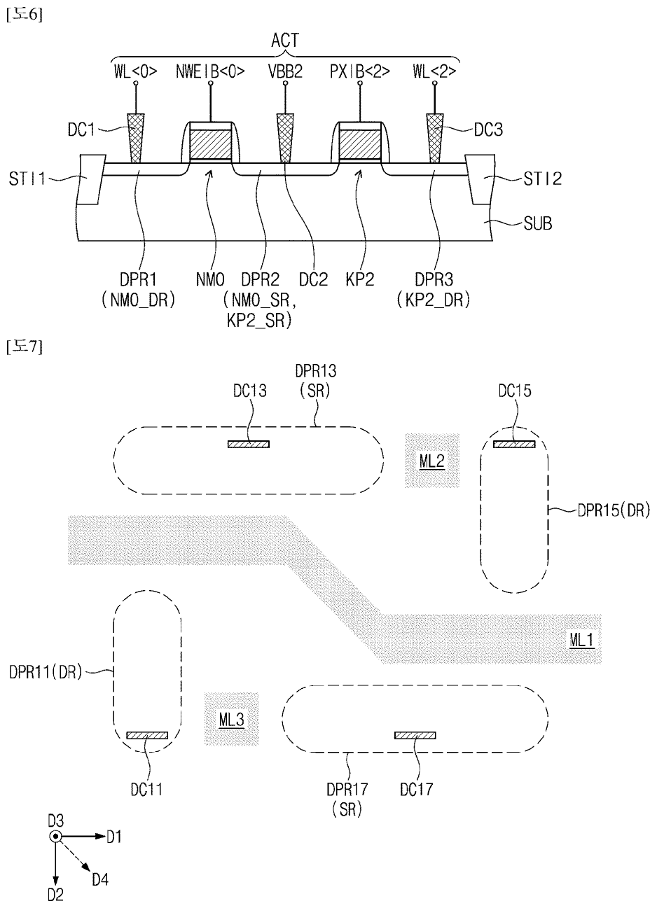

FIGS. 5 and 6 are diagrams for describing embodiments of the placement of transistors included in sub-word line drivers of FIG. 3.

Referring to FIGS. 3 and 5, some 133b of sub-word line drivers may include the sub-word line drivers SWD0, SWD2, SWD4, and SWD6, and each of the sub-word line drivers SWD0, SWD2, SWD4, and SWD6 may include a pull-up transistor, a pull-down transistor, and a keeping transistor.

In an embodiment, the sub-word line drivers SWD0, SWD2, SWD4, and SWD6 may be formed on the semiconductor substrate.

A source region of a pull-down transistor included in one sub-word line driver and a source region of a keeping transistor included in another sub-word line driver may be disposed on the semiconductor substrate to share one doping region on the semiconductor substrate.

In an embodiment, the sub-word line driver SWD0 may include the pull-down transistor NM0 and the keeping transistor KP0, and the sub-word line driver SWD2 may include the pull-down transistor NM2 and the keeping transistor KP2. For example, the source regions of the pull-down transistor NM2 and the keeping transistor KP0 may be disposed to share a doping region SHRD_DPR1-1, and the source regions of the pull-down transistor NM0 and the keeping transistor KP2 may be disposed to share a doping region SHRD_DPR2-1.

In an embodiment, the sub-word line driver SWD4 may include the pull-down transistor NM4 and the keeping transistor KP4, and the sub-word line driver SWD6 may include the pull-down transistor NM6 and the keeping transistor KP6. For example, the source regions of the pull-down transistor NM6 and the keeping transistor KP4 may be disposed to share a doping region SHRD_DPR1-2, and the source regions of the pull-down transistor NM4 and the keeping transistor KP6 may be disposed to share a doping region SHRD DPR2-2.

Referring to FIGS. 5 and 6, an active region ACT which is placed between device isolation layers ST1 and ST2 may be defined on a semiconductor substrate SUB.

Doping regions DPR1, DPR2, and DPR3 may be formed in the active region ACT, and the pull-down transistor NM0 included in the sub-word line driver SWD0 and the keeping transistor KP2 included in the sub-word line driver SWD2 may be formed.

The pull-down transistor NM0 may receive the word line enable signal NWEIB<0>through the gate terminal and may include a drain region NM0_DR connected to the word line WL<0>through a direct contact DC1 and a source region NM0_SR connected to the terminal providing the negative voltage VBB2 through a direct contact DC2. The keeping transistor KP2 may receive the sub-word line driver control signal PXIB<2>through the gate terminal and may include a drain region KP2_DR connected to the word line WL<2>through a direct contact DC3 and a source region KP2_SR connected to the terminal providing the negative voltage VBB2 through the direct contact DC2.

As illustrated in FIG. 6, the source regions of the pull-down transistor NM0 and the keeping transistor KP2 may be disposed to share one doping region (e.g., DPR2). Although not illustrated in FIG. 6, to be similar to the example illustrated in FIG. 6, the source regions of the pull-down transistor NM2 and the keeping transistor KP0, the source regions of the pull-down transistor NM6 and the keeping transistor KP4, and the source regions of the pull-down transistor NM4 and the keeping transistor KP6 may be disposed to share one doping regions.

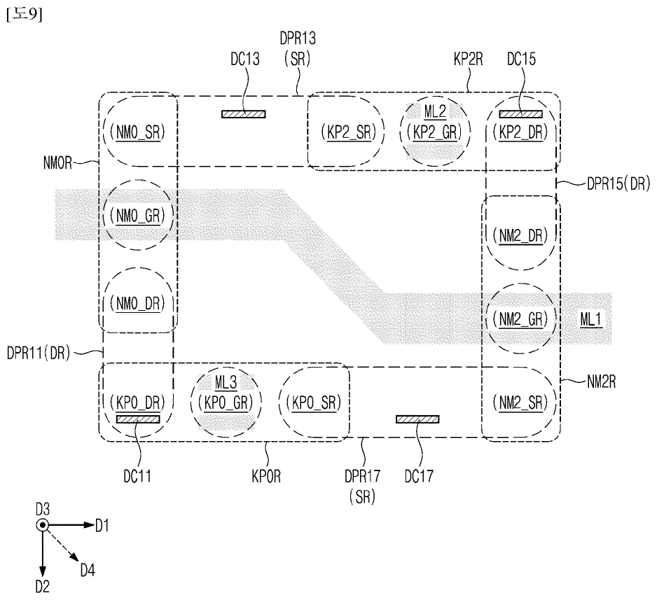

FIGS. 7 and 8 are diagrams for describing an embodiment of the placement of doping regions or metal lines included in sub-word line drivers of FIG. 1.

A plan view of the semiconductor substrate described with reference to FIGS. 1, 2, 5, and 6 when seen in the vertical direction is illustrated in FIG. 7, and only regions corresponding to the pull-down transistors NM0 and NM2 and the keeping transistors KP0 and KP2 of some (e.g., SWD0 and SWD2) of the sub-word line drivers SWD0, SWD2, SWD4, and SWD6 of FIG. 5 may be included in a semiconductor substrate of FIG. 7. Directions D1, D2, and D3 may be orthogonal, and a direction D4 may indicate a direction between D1 and D2. The directions D1, D2, D3, and D4 may be used in common to describe a semiconductor memory device according to an embodiment of the present disclosure.

Referring to FIG. 7, doping regions DPR11, DPR13, DPR15, and DPR17 and metal lines ML1, ML2, and ML3 may be formed in the semiconductor substrate, and direct contacts DC11, DC13, DC15, and DC17 for applying given signals or voltages may be formed in the doping regions DPR11, DPR13, DPR15, and DPR17.

In an embodiment, the doping regions DPR11, DPR13, DPR15, and DPR17 may be disposed on the semiconductor substrate to be spaced from each other.

In an embodiment, drain regions may be formed in the doping regions DPR11 and DPR15, and source regions may be formed in the doping regions DPR13 and DPR17. For example, the drain regions of the pull-down transistor NM0 and the keeping transistor KP0 may be formed in the doping region DPR11, and the source regions of the pull-down transistor NM0 and the keeping transistor KP2 may be formed in the doping region DPR13. The drain regions of the keeping transistor KP2 and the pull-down transistor NM2 may be formed in the doping region DPR15, and the source regions of the pull-down transistor NM2 and the keeping transistor KP0 may be formed in the doping region DPR17.

The metal lines ML1, ML2, and ML3 may be electrically connected to the gates of the pull-down transistors NM0 and NM2 and the keeping transistors KP0 and KP2. For example, the metal line ML1 may be electrically connected to the gates of the pull-down transistors NM0 and NM2, the metal line ML2 may be electrically connected to the gate of the keeping transistor KP2, and the metal line ML3 may be electrically connected to the gate of the keeping transistor KP0.

In an embodiment, gate signals (e.g., NWEIB<0>, PXIB<0>, and PXIB<2>) may be provided to the pull-down transistors NM0 and NM2 and the keeping transistors KP0 and KP2 through the metal lines ML1, ML2, and ML3. For example, a word line enable signal (e.g., NWEIB<0>) may be applied to the pull-down transistors NM0 and NM2 through the metal line ML1, a sub-word line driver control signal (e.g., PXIB<2>) may be applied to the keeping transistor KP2 through the metal line ML2, and a sub-word line driver control signal (or a keeping control signal) (e.g., PXIB<0>) may be applied to the keeping transistor KP0 through the metal line ML3.

The direct contacts DC11, DC13, DC15, and DC17 may be disposed on the doping regions DPR11, DPR13, DPR15, and DPR17. For example, the direct contact DC11 may be disposed on the doping region DPR11, the direct contact DC13 may be disposed on the doping region DPR13, the direct contact DC15 may be disposed on the doping region DPR15, and the direct contact DC17 may be disposed on the doping region DPR17.

In an embodiment, a negative voltage (e.g., VBB2 of FIG. 1) may be provided to the pull-down transistor NM0 and NM2 and the keeping transistors KP0 and KP2 through the direct contacts DC13 and DC17. For example, the pull-down transistor NM0 and the keeping transistor KP2 may receive the negative voltage through the direct contact DC13, and the pull-down transistor NM2 and the keeping transistor KP0 may receive the negative voltage through the direct contact DC17.

Only the metal lines ML1, ML2, and ML3 are illustrated in FIG. 8. Referring to FIG. 8, the metal line ML1 may extend in the first direction D1 as much as a first length L1 (e.g., from point P1 to point P2), may then extend in the second direction D4 different from the first direction D1 as much as a second length L2 (e.g., from point P2 to point P3), and may then extend in the first direction D1 as much as a third length L3 (e.g., from point P3 to point P4).

In an embodiment, the first direction D1 may be a direction in which word lines WL<0>and WL<2>which the sub-word line drivers SWD0 and SWD2 drive extend, and the second direction D4 may form a given angle of θ1 with the first direction D1. For example, the angle θ1 may have 45 degrees or may have a value as close as 45 degrees.

The metal line ML2 and the metal line ML3 may be disposed to be symmetrical with respect to the metal line ML1 extending in the second direction D4.

In an embodiment, the metal line ML2 and the metal line ML3 may be disposed on a virtual line VL1 perpendicular to the second direction D4.

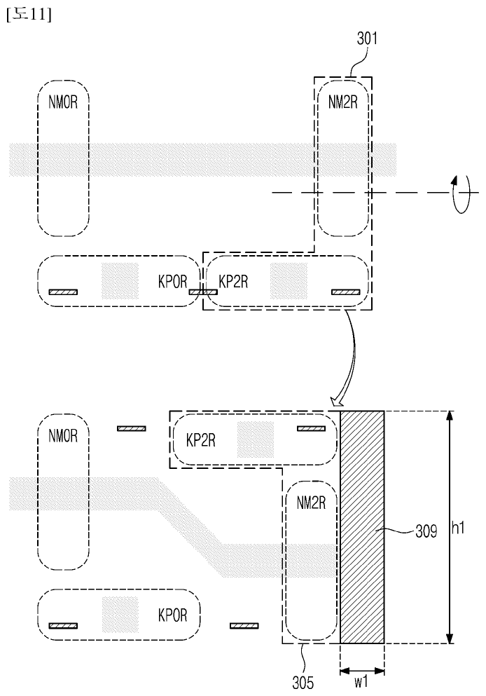

In an embodiment, the metal line ML2 and the metal line ML3 may be disposed on another virtual line forming a given angle of θ2 with the line VL1. For example, the angle θ2 may be 0 degree or may have a value as close as 0 degree. A point P23 at which the metal line ML1 extending in the second direction D4 and the line VL1 cross each other will be described with reference to FIG. 10. The point P23 may be used as a criterion for forming metal lines or gate regions of given keeping transistors.

FIGS. 9 and 10 are diagrams for describing an embodiment of the placement of transistors, doping regions, or metal lines included in sub-word line drivers of FIG. 1.

A plan view of a semiconductor substrate substantially the same as the semiconductor substrate of FIG. 7 is illustrated in FIG. 9, and only regions corresponding to the pull-down transistors NM0 and NM2 and the keeping transistors KP0 and KP2 of some (e.g., SWD0 and SWD2) of the sub-word line drivers SWD0, SWD2, SWD4, and SWD6 of FIG. 5 may be included in a semiconductor substrate of FIG. 9. In FIGS. 7 and 9, components having the same reference numerals/signs may perform substantially the same functions.

Referring to FIG. 9, the doping regions DPR11, DPR13, DPR15, and DPR17 and the metal lines ML1, ML2, and ML3 may be formed on the semiconductor substrate, and transistor regions NM0R and NM2R in which the pull-down transistors NM0 and NM2 are respectively formed and transistor regions KP0R and KP2R in which the keeping transistors KP0 and KP2 are respectively formed may be further formed on the semiconductor substrate.

In an embodiment, the source region NM0_SR of the pull-down transistor NM0 and the source region KP2_SR of the keeping transistor KP2 may be formed in the doping region DPR13. For example, the source regions NM0_SR and KP2_SR of the pull-down transistor NM0 and the keeping transistor KP2 may be disposed to share the doping region DPR13.

In an embodiment, a source region NM2_SR of the pull-down transistor NM2 and a source region KP0_SR of the keeping transistor KP0 may be formed in the doping region DPR17. For example, the source regions NM2_SR and KP0_SR of the pull-down transistor NM2 and the keeping transistor KP0 may be disposed to share the doping region DPR17.

In an embodiment, the drain region NM0_DR of the pull-down transistor NM0 and a drain region KP0_DR of the keeping transistor KP0 may be formed in the doping region DPR11. For example, the drain regions NM0_DR and KP0_DR of the pull-down transistor NM0 and the keeping transistor KP0 may be disposed to share the doping region DPR11.

In an embodiment, a drain region NM2_DR of the pull-down transistor NM2 and the drain region KP2_DR of the keeping transistor KP2 may be formed in the doping region DPR15. For example, the drain regions NM2_DR and KP2_DR of the pull-down transistor NM2 and the keeping transistor KP2 may be disposed to share the doping region DPR15.

In an embodiment, the doping region DPR13 may be referred to as a “first doping region”, the doping region DPR17 may be referred to as a “second doping region”, the doping region DPR11 may be referred to as a “third doping region”, and the doping region DPR15 may be referred to as a “fourth doping region”. In this case, the first to fourth doping regions may be disposed clockwise in order of the first doping region, the fourth doping region, the second doping region, and the third doping region with respect to a virtual center axis perpendicular to the semiconductor substrate. In this case, the first doping region and the third doping region may be disposed to form the point symmetry with the second doping region and the fourth doping region.

In an embodiment, the pull-down transistor NM0 and the keeping transistor KP0 may be disposed on the semiconductor substrate to form the point symmetry with the pull-down transistor NM2 and the keeping transistor KP2.

A gate region NM0_GR in which the gate of the pull-down transistor NM0 is formed may be disposed in a region where the metal line ML1 and the transistor region NM0R overlap each other, and a gate region NM2_GR in which the gate of the pull-down transistor NM2 is formed may be disposed in a region where the metal line ML1 and the transistor region NM2R overlap each other. A gate region KP2_GR in which the gate of the keeping transistor KP2 is formed may be disposed in a region where the metal line ML2 and the transistor region KP2R overlap each other, and a gate region KP0_GR in which the gate of the keeping transistor KP0 is formed may be disposed in a region where the metal line ML3 and the transistor region KP0R overlap each other.

Referring to FIGS. 9 and 10, virtual lines VL2-1 and VL2-2 which pass through the point P23 and cross each other to be perpendicular may be defined on the semiconductor substrate. For example, as described with reference to FIG. 8, the point P23 may be a point at which the metal line ML1 extending in the second direction DR and the line VL1 cross each other.

The semiconductor substrate may be partitioned to four regions based on the lines VL2-1 and VL2-2, and the gate regions NM0_GR, NM2_GR, KP0_GR, and KP2_GR of the pull-down transistor NM0, the pull-down transistor NM2, the keeping transistor KP0, and the keeping transistor KP2 may be respectively disposed in the four regions.

In an embodiment, the gate region NM0_GR and the gate region NM2_GR may be disposed to be spaced apart from each other and may be disposed to be point-symmetrical with respect to the point P23. The gate region KP0_GR and the gate region KP2_GR may be disposed to be spaced apart from each other and may be disposed to be point-symmetrical with respect to the point P23.

In an embodiment, the gate regions NM0_GR and KP0_GR and the gate regions KP2_GR and NM2_GR may be disposed to be spaced apart from each other and may be disposed to be point-symmetrical with respect to the point P23. The gate regions NM0_GR and KP2_GR and the gate regions KP0 GR and NM2_GR may be disposed to be spaced apart from each other and may be disposed to be point-symmetrical with respect to the point P23.

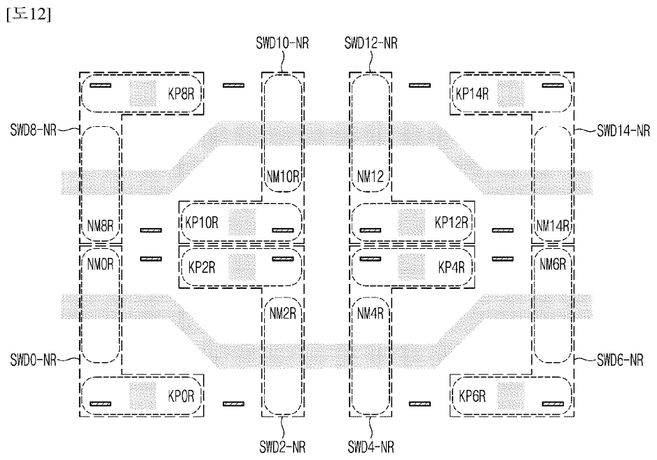

FIG. 11 is a diagram for describing the placement of sub-word line drivers of FIG. 1.

The transistor regions NM0R, KP0R, NM2R, and KP2R are illustrated in FIG. 11. The transistor regions NM0R, KP0R, NM2R, and KP2R are substantially the same as the transistor regions NM0R, KP0R, NM2R, and KP2R described with reference to FIG. 9.

Referring to FIGS. 9 and 11, transistor regions included in a sub-word line driver according to embodiments of the present disclosure may be implemented by changing the placement of transistor regions according to the prior art. For example, the placement of the transistor regions NM2R and KP2R among the transistor regions NM0R, KP0R, NM2R, and KP2R may be implemented by changing the placement (e.g., 301) according to the prior art to any other placement (e.g., 305).

In an embodiment, each of the placements 301 and 305 may include the transistor region NM2R where the pull-down transistor NM2 is formed and the transistor region KR2R where the keeping transistor KP2 is formed. As illustrated in FIG. 11, the placement 305 may be implemented by rotating the placement 301 as much as 180 degrees about a virtual line passing through the drain region of the pull-down transistor NM2.

As the placement 301 is changed to the placement 305, the line symmetry which the transistor regions NM0R and KP0R form with the transistor regions NM2R and KP2R may be changed to the point symmetry which the transistor regions NM0R and KP0R form with the transistor regions NM2R and KP2R. In this case, the shortest distance between the transistor region NM2R and the transistor region KR0R may decrease, and the shortest distance between the transistor region KP2R and the transistor region NM0R may decrease.

As the placement 301 is changed to the placement 305, the source region NM0_SR of the pull-down transistor NM0 and the source region KP2_SR of the keeping transistor KP2 may be disposed to share one doping region, and the source region NM2_SR of the pull-down transistor NM2 and the source region KP0_SR of the keeping transistor KP0 may be disposed to share one doping region. In this case, the area on the semiconductor substrate, which is occupied by a portion of a sub-word line driver, may be decreased as much as the size (e.g., w1×h1) of a region 309.

As the placement 301 is changed to the placement 305, the metal lines may be formed as described with reference to FIG. 8.

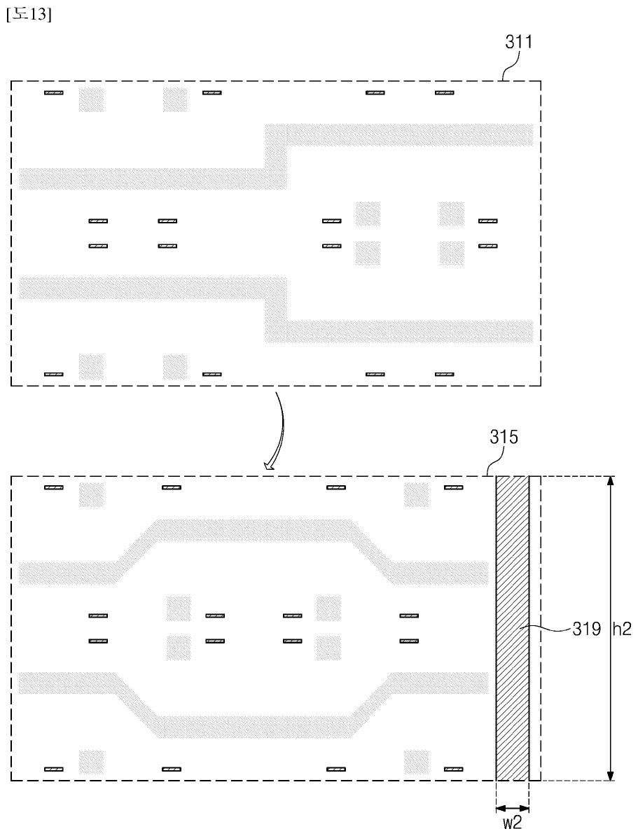

FIG. 12 is a diagram for describing an embodiment of the placement of transistors, doping regions, or metal lines included in sub-word line drivers according to an embodiment of the present disclosure.

A plan view of a semiconductor substrate substantially the same as the semiconductor substrate of FIG. 7 is illustrated in FIG. 12. The semiconductor substrate of FIG. 12 may include the regions corresponding to the pull-down transistors NM0, NM2, NM4, and NM6 and the keeping transistors KP0, KP2, KP4, and KP6 of the sub-word line drivers SWD0, SWD2, SWD4, and SWD6 of FIG. 5, and may further include regions corresponding to pull-down transistors NM8, NM10, NM12, and NM14 and keeping transistors KP8, KP10, KP12, and KP14 of the sub-word line drivers SWD8, SWD10, SWD12, and SWD14 not illustrated in FIG. 5. Although not illustrated in FIG. 12, in a manner identical or similar to the manner described with reference to FIGS. 5, 6, and 9, doping regions may be shared between the pull-down transistors NM0, NM2, NM4, NM6, NM8, NM10, NM12, and NM14 and the keeping transistors KP0, KP2, KP4, KP6, KP8, KP10, KP12, and KP14 of the sub-word line drivers SWD0, SWD2, SWD4, SWD6, SWD8, SWD10, SWD12, and SWD14.

Referring to FIGS. 2, 3, and 12, the sub-word line drivers SWD8, SWD10, SWD12, and SWD14 may respectively activate the word lines WL<8>, WL<10>, WL<12>, and WL<14>, and the word lines WL<8>, WL<10>, WL<12>, and WL<14>may be word lines which extend to one side of the memory cell array in the same direction as the word lines WL<0>, WL<2>, WL<4>, and WL<6>and are adjacent to each other.

In an embodiment, in the semiconductor substrate, a sub-word line driver region SWD0-NR including the transistor regions NM0R and KP0R where the pull-down transistor NM0 and the keeping transistor KP0 are formed may be defined, and a sub-word line driver region SWD2-NR including the transistor regions NM2 and KP2R where the pull-down transistor NM2 and the keeping transistor KP2 are formed may be defined. Sub-word line driver regions SWD4-NR, SWD6-NR, SWD8-NR, SWD10-NR, SWD12-NR, and SWD14-NR may be defined as in the above description. The sub-word line driver regions SWD0-NR, SWD2-NR, SWD4-NR, SWD6-NR, SWD8-NR, SWD10-NR, SWD12-NR, and SWD14-NR may respectively include NMOS transistors SWD0-N, SWD2-N, SWD4-N, SWD6-N, SWD8-N, SWD10-N, SWD12-N, and SWD14-N of the sub-word line drivers SWD0, SWD2, SWD4, SWD6, SWD8, SWD10, SWD12, and SWD14. In this case, all the sub-word line driver regions SWD0-NR and SWD2-NR may be disposed to form the line symmetry with all the sub-word line driver regions SWD4-NR and SWD6-NR. All the sub-word line driver regions SWD8-NR and SWD10-NR may be disposed to form the line symmetry with all the sub-word line driver regions SWD12-NR and SWD14-NR. All the sub-word line driver regions SWD0-NR, SWD2-NR, SWD4-NR, and SWD6-NR may be disposed to form the line symmetry with all the sub-word line driver regions SWD8-NR, SWD10-NR, SWD12-NR, and SWD14-NR.

In an embodiment, as the sub-word line driver regions SWD0-NR and SWD2-NR and the sub-word line driver regions SWD8-NR and SWD10-NR are adjacent to each other, the sharing of doping regions may be additionally caused. For example, the source region of the pull-down transistor NM0 included in the sub-word line driver region SWD0-NR and the source region of the keeping transistor KP2 included in the sub-word line driver region SWD2-NR may share one doping region. The source region of the pull-down transistor NM8 included in the sub-word line driver region SWD8-NR and the source region of the keeping transistor KP10 included in the sub-word line driver region SWD10-NR may share one doping region. Also, all the source regions of the pull-down transistors NM0 and NM8 and the keeping transistors KP2 and KP10 may share one doping region. For example, the source region of the pull-down transistor KP4 included in the sub-word line driver region SWD4-NR and the source region of the pull-down transistor NM6 included in the sub-word line driver region SWD6-NR may share one doping region. The source region of the pull-down transistor KP12 included in the sub-word line driver region SWD12-NR and the source region of the pull-down transistor NM14 included in the sub-word line driver region SWD14-NR may share one doping region. Also, all the source regions of the pull-down transistors NM6 and NM14 and the keeping transistors KP4 and KP12 may share one doping region.

In an embodiment, NMOS transistors of first to fourth sub-word line drivers may be respectively disposed in the sub-word line driver regions SWD0-NR, SWD2-NR, SWD4-NR, and SWD6-NR. The first sub-word line driver may include a first pull-down transistor and a first keeping transistor, and the second sub-word line driver may include a second pull-down transistor and a second keeping transistor. The third sub-word line driver may include a third pull-down transistor and a third keeping transistor and may, and the fourth sub-word line driver may include a fourth pull-down transistor and a fourth keeping transistor.

In an embodiment, a first metal line may be electrically connected to gates of the first to fourth pull-down transistors, and a second metal line may be electrically connected to a gate of the first keeping transistor. A third metal line may be electrically connected to a gate of the second keeping transistor, a fourth metal line may be electrically connected to a gate of the third keeping transistor, and a fifth metal line may be electrically connected to a gate of the fourth keeping transistor.

In an embodiment, the third metal line and the fourth metal line may be formed of one metal line and may provide the same sub-word line driver control signal to the gates of the second keeping transistor and the third keeping transistor. For example, the same sub-word line driver control signal (e.g., PXIB<2>of FIG. 5) may be provided to gates of keeping transistors included in the transistor regions KP2R and KP10R. For example, the same sub-word line driver control signal (e.g., PXIB<4>of FIG. 5) may be provided to gates of keeping transistors included in the transistor regions KP4R and KP12R.

In an embodiment, the first metal line may extend in a first direction as much as a first length, may then extend in a second direction different from the first direction as much as a second length, and may then extend in the first direction as much as a third length. After the first metal line extends in the first direction as much as the third length, the first metal line may extend in a third direction different from the first direction as much as the second length and may then extend in the first direction as much as a fifth length. In this case, the first direction may be a direction in which word lines of the memory cell array extend to one side. The second direction may be form an angle of 45 degrees with the first direction, and the third direction may form an angle of 45 degrees with the first direction and may form an angle of 90 degrees with the second direction.

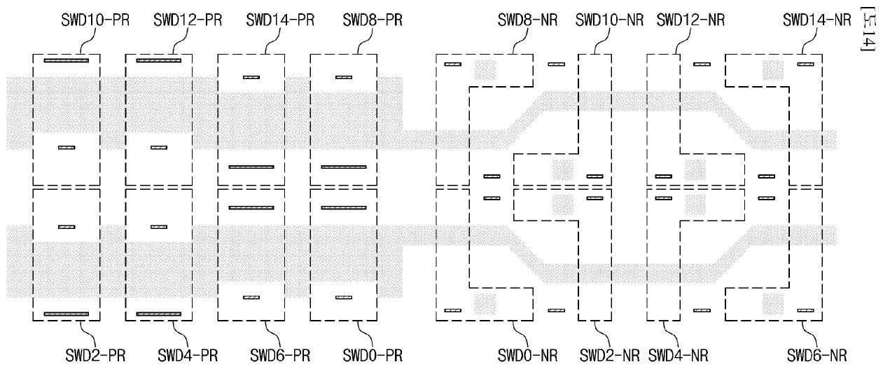

FIG. 13 is a diagram for describing the placement of sub-word line drivers of FIG. 12.

Referring to FIGS. 11, 12, and 13, transistor regions included in a sub-word line driver according to embodiments of the present disclosure may be implemented by partially changing the placement of transistor regions according to the prior art. For example, the placement of the sub-word line driver region may be implemented by changing the placement (e.g., 311) according to the prior art to any other placement (e.g., 315). In this case, the area on the semiconductor substrate, which is occupied by a portion of a sub-word line driver, may be decreased as much as the size (e.g., w2×h2) of a region 319.

As the placement 311 is changed to the placement 315, the metal lines may be formed as described with reference to FIG. 8.

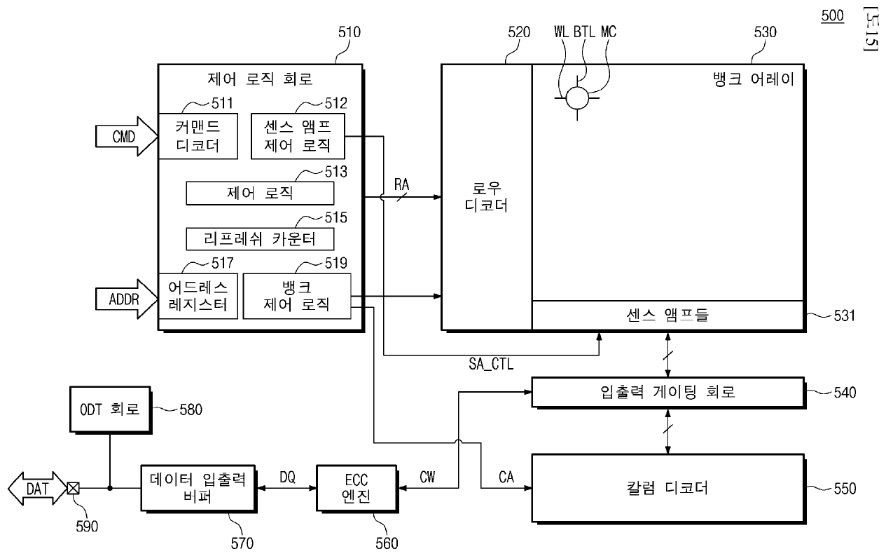

FIG. 14 is a diagram illustrating an embodiment of the placement of sub-word line drivers according to an embodiment of the present disclosure.

A plan view of a semiconductor substrate substantially the same as the semiconductor substrate of FIG. 7 is illustrated in FIG. 14. The semiconductor substrate of FIG. 14 may include the regions corresponding to the NMOS transistors SWD0-N, SWD2-N, SWD4-N, SWD6-N, SWD8-N, SWD10-N, SWD12-N, and SWD14-N of the sub-word line drivers SWD0, SWD2, SWD4, SWD6, SWD8, SWD10, SWD12, and SWD14, and may further include regions corresponding to PMOS transistors SWD0-P, SWD2-P, SWD4-P, SWD6-P, SWD8-P, SWD10-P, SWD12-P, and SWD14-P of the sub-word line drivers SWD0, SWD2, SWD4, SWD6, SWD8, SWD10, SWD12, and SWD14.

Referring to FIGS. 2, 3, 12, and 14, the sub-word line drivers SWD8, SWD10, SWD12, and SWD14 may respectively activate the word lines WL<8>, WL<10>, WL<12>, and WL<14>, and the word lines WL<8>, WL<10>, WL<12>, and WL<14>may be word lines which extend to one side of the memory cell array in the same direction as the word lines WL<0>, WL<2>, WL<4>, and WL<6>and are adjacent to each other. Although not illustrated in FIG. 14, in a manner identical or similar to the manner described with reference to FIGS. 5, 6, 9, and 12, doping regions may be shared between the pull-down transistors NM0, NM2, NM4, NM6, NM8, NM10, NM12, and NM14 and the keeping transistors KP0, KP2, KP4, KP6, KP8, KP10, KP12, and KP14 of the sub-word line drivers SWD0, SWD2, SWD4, SWD6, SWD8, SWD10, SWD12, and SWD14.

In an embodiment, in the semiconductor substrate, a sub-word line driver region SWD0-PR including a transistor region where the pull-up transistor PM0 is formed may be defined, and a sub-word line driver region SWD2-PR including a transistor region where the pull-up transistor PM2 is formed may be defined. Sub-word line driver regions SWD4-PR, SWD6-PR, SWD8-PR, SWD10-PR, SWD12-PR, and SWD14-PR may be defined as in the above description. The sub-word line driver regions SWD0-PR, SWD2-PR, SWD4-PR, SWD6-PR, SWD8-PR, SWD10-PR, SWD12-PR, and SWD14-PR may respectively include the PMOS transistors SWD0-P, SWD2-P, SWD4-P, SWD6-P, SWD8-P, SWD10-P, SWD12-P, and SWD14-P of the sub-word line drivers SWD0, SWD2, SWD4, SWD6, SWD8, SWD10, SWD12, and SWD14. In this case, all the sub-word line driver regions SWD4-PR, SWD6-PR, SWD8-PR, SWD10-PR, SWD12-PR, and SWD14-PR may be disposed on first sides of all the sub-word line driver regions SWD0-NR, SWD2-NR, SWD4-NR, SWD6-NR, SWD8-NR, SWD10-NR, and SWD12-NR. All the sub-word line driver regions SWD0-PR, SWD2-PR, SWD4-PR, and SWD6-PR may be disposed to form the line symmetry with all the sub-word line driver regions SWD8-PR, SWD10-PR, SWD12-PR, and SWD14-PR.

In FIG. 14, the order in which the respective sub-word line driver regions SWD0-PR, SWD2-PR, SWD4-PR, SWD6-PR, SWD8-PR, SWD10-PR, SWD12-PR, SWD14-PR, SWD0-NR, SWD2-NR, SWD4-NR, SWD6-NR, SWD8-NR, SWD10-NR, SWD12-NR, and SWD14-NR are disposed is provided only as an example.

In an embodiment, when the order of the sub-word line driver regions SWD0-NR, SWD2-NR, SWD4-NR, SWD6-NR, SWD8-NR, SWD10-NR, SWD12-NR, and SWD14-NR is changed, the order of the sub-word line driver regions SWD0-PR, SWD2-PR, SWD4-PR, SWD6-PR, SWD8-PR, SWD10-PR, SWD12-PR, and SWD14-PR respectively corresponding thereto may also be changed together.

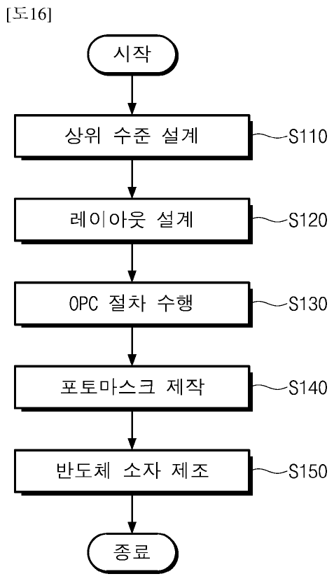

FIG. 15 is a block diagram illustrating a semiconductor memory device including sub-word line drivers according to an embodiment of the present disclosure.

Referring to FIG. 15, a semiconductor memory device 500 may include a control logic circuit 510, a row decoder 520, a bank array 530, sense amplifiers 531, an input/output gating circuit 540, a column decoder 550, an ECC engine 560, a data input/output buffer 570, and an on-die termination (ODT) circuit 580. The control logic circuit 510 may include a command decoder 511, sense amplifier control logic 512, a mode register 513, a refresh counter 515, an address register 517, and bank control logic 519. For example, the semiconductor memory device 500 may be a volatile memory device and in particular, may be a DRAM.

The bank array 530 may include a plurality of bank arrays. The row decoder 520 may include a plurality of bank row decoders respectively connected to the plurality of bank arrays, the column decoder 550 may include a plurality of bank column decoders respectively connected to the plurality of bank arrays, and the sense amplifiers 531 may include a plurality of bank sense amplifiers respectively connected to the plurality of bank arrays. The plurality of bank arrays, the plurality of bank row decoders, the plurality of bank column decoders, and the plurality of bank sense amplifiers may constitute a plurality of banks. Each of the plurality of bank arrays may include a plurality of memory cells MCs which are formed at intersections of a plurality of word lines WLs and a plurality of bit lines BLs. The row decoder 520 may correspond to the row decoder 190 of FIG. 2, and the sub-word line drivers SWD1, SWD2, SWD3, SWD4, SWD5, SWD6, SWD7, etc. of FIG. 2 may be included in the bank array 530 and may activate corresponding word lines among the plurality of word lines WLs.

The address register 517 may receive an address ADDR including a bank address, a row address, and a column address from a memory controller. The address register 517 may provide the bank address to the bank control logic 519, may provide the row address to the row decoder 520, and may provide the column address to the column decoder 550.

The bank control logic 519 may generate a bank control signal in response to the bank address. A bank row decoder and a bank column decoder which correspond to the bank address may be activated based on the bank control signal.

The refresh counter 515 may generate a refresh row address which sequentially increases or decreases under control of the control logic circuit 510. Activated bank column decoders from among the plurality of bank column decoders may activate the sense amplifiers 531, which correspond to the bank address, the row address, and the column address, by using the input/output gating circuit 540.

A codeword CW read from one of the plurality of bank arrays may be sensed by sense amplifiers corresponding to the one bank array, the ECC engine 560 may perform ECC decoding on the sensed codeword CW, and a DQ signal may be provided to the memory controller through the data input/output buffer 295 as an ECC decoding result. Data DAT which are transmitted from an input/output pad 590 to the data input/output buffer 295 may be multi-level data. The data input/output buffer 295 may include reception drivers for encoding the multi-level data and may receive reference voltages for the encoding.

The data DAT to be written in one of the plurality of bank arrays may be provided to the ECC engine 560, the ECC engine 560 may generate parity bits based on the data DAT and may provide a codeword including the data DAT and the parity bits to the input/output gating circuit 540, and the input/output gating circuit 540 may write the codeword in the one bank array.

The ODT circuit 580 may be connected to the data input/output pad 590 and the data input/output buffer 570 and may perform impedance matching.

The control logic circuit 510 may control the operation of the memory device 500. For example, the control logic circuit 510 may generate control signals such that the memory device 500 performs the write operation or the read operation. The control logic circuit 510 may include the command decoder 511 which decodes a command CMD received from the memory controller and the mode register 513 for setting an operation mode of the memory device 500. For example, the command decoder 511 may decode a write enable signal, a row address strobe signal, a column address strobe signal, a chip select signal, etc. and may generate the control signals corresponding to the command CMD.

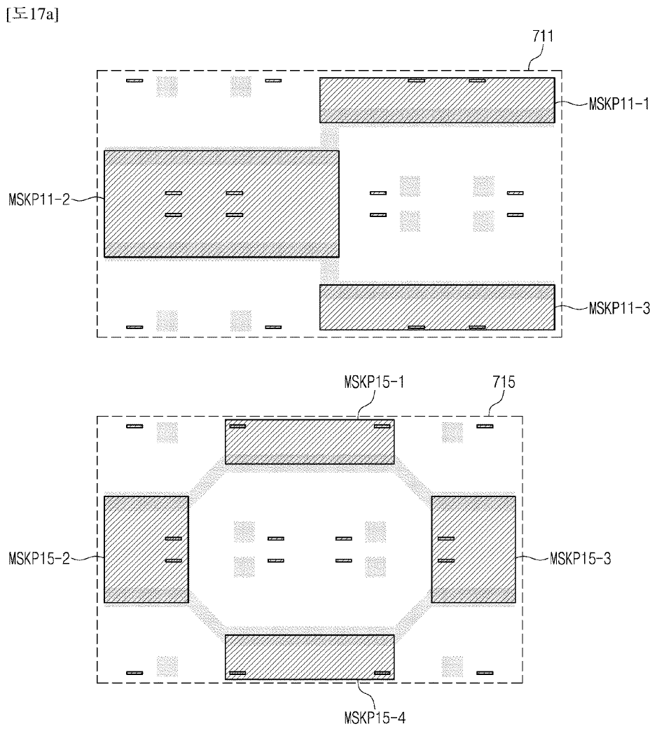

FIG. 16 is a flowchart illustrating a semiconductor memory device designing and manufacturing method according to an embodiment of the present disclosure.

Referring to FIG. 16, a high level design of a semiconductor integrated circuit may be performed by using a computer system (S110). The high level design may mean describing an integrated circuit targeted for design as an high level language of a computer language. For example, a high level language such as a C language may be used. Circuits designed by the high level design may be more specifically expressed by register transfer level (RTL) coding or simulation. In addition, the code generated by the register transfer level coding may be converted into a netlist and may be synthesized into an entire semiconductor device. The synthesized schematic circuit may be verified by a simulation tool, and an adjustment process may be accompanied depending on the verification result.

A layout design for implementing a logically completed semiconductor integrated circuit on a silicon substrate may be performed (S120). For example, the layout design may be performed by referring to the schematic circuit synthesized in the high level design or the netlist corresponding thereto. The layout design may include a routing procedure for placing and connecting various cells provided in a cell library depending on a prescribed design rule. In designing a layout associated with embodiments of the present disclosure, designing a plurality of metal lines may be included. The plurality of metal lines may correspond to a plurality of metal layers sequentially stacked on the silicon substrate. Routing by which data paths are connected may be performed while each metal line is disposed.

The cell library for the layout design may also include information about an operation, a speed, and power consumption of a cell. The cell library for representing a circuit of a specific gate level as a layout is defined in most layout design tools. The layout may be a procedure for defining a shape or a size of a pattern for constituting transistors, doping regions, and metal lines to be actually formed on the silicon substrate. For example, layout patterns such as PMOS, NMOS, N-WELL, gate lines, and metal lines to be placed thereon may be appropriately disposed to actually form an inverter circuit on the silicon substrate. To this end, it may be possible to search for and select appropriate inverters among inverters defined in advance in the cell library. In addition, routing for the selected and placed cells may be performed. Most of a series of processes may be performed automatically or passively by the layout design tool.

After the routing, verification of the layout may be performed to determine whether there is a part which violates the design rule. Items to be verified may include a design rule check (DRC) which verifies whether the layout is in line with the design rule, an electronic rule check (ERC) which verifies whether internal electrical connection is correctly made without disconnection, and a layout vs schematic (LVS) which verifies whether the layout matches the gate-level netlist.

An optical proximity correction (OPC) procedure may be performed (S130). The layout patterns obtained through the layout design may be implemented on the silicon substrate by using a photolithography process. In this case, the optical proximity correction may be a technique for correcting a distortion phenomenon capable of occurring in the photolithography process. That is, through the optical proximity correction, the distortion phenomenon such as refraction or a process effect caused due to a light characteristic during exposure using the pattern thus laid out may be corrected. Shapes and positions of the designed layout patterns may be slightly changed while performing the optical proximity correction.

A photomask may be manufactured based on the layout changed by the optical proximity correction (S140). In general, the photomask may be manufactured by depicting the layout patterns by using a chromium thin layer applied on a glass substrate.

A semiconductor device may be manufactured by using the generated photomask (S150). Various types of exposure and etching processes may be repeated in the process of manufacturing the semiconductor device by using the photomask. Through these processes, patterns implemented in the process of designing a layout on the silicon substrate may be sequentially formed.

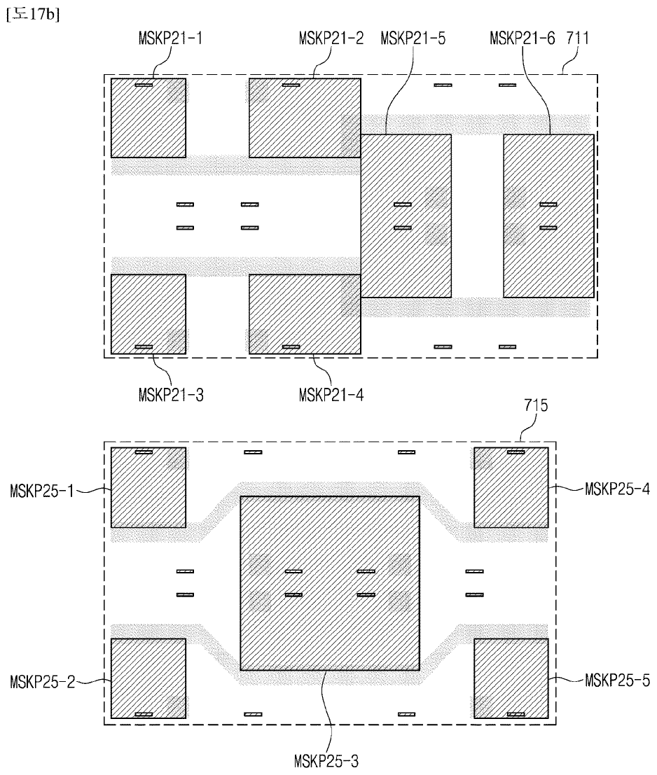

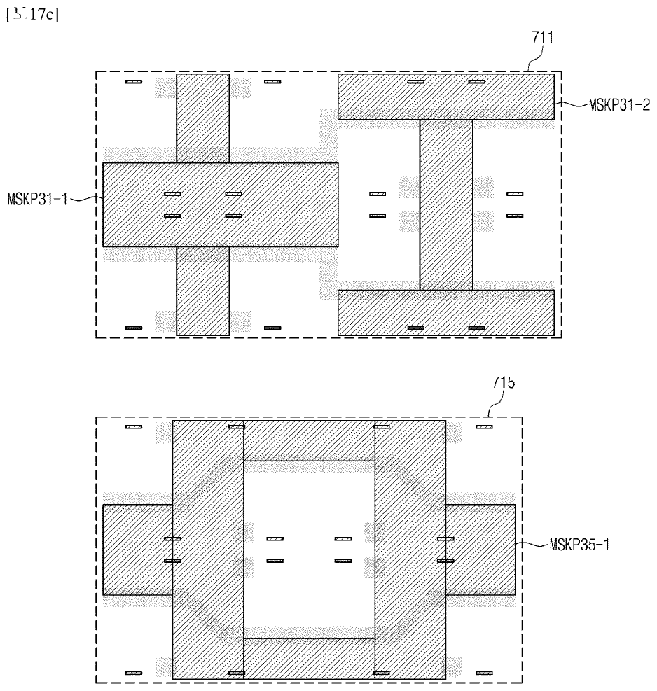

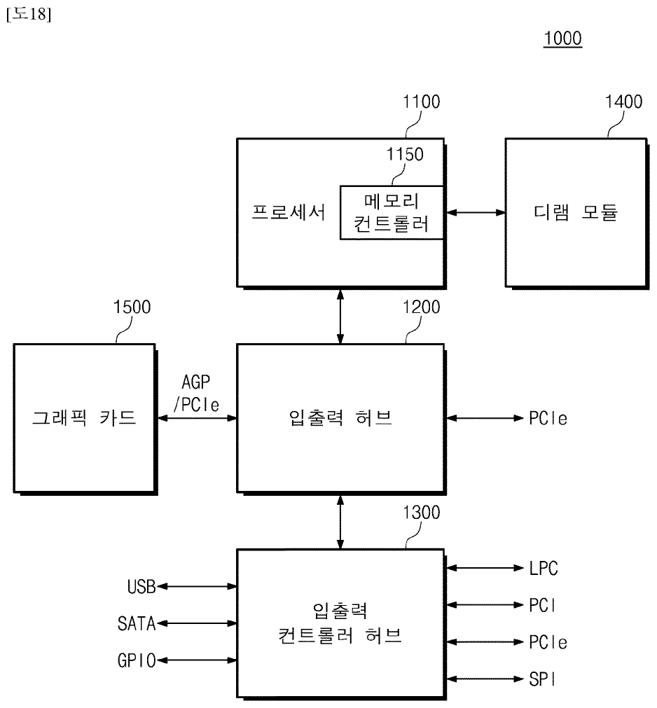

FIGS. 17a, 17b, and 17c are diagrams for describing photo masks for forming patterns included in sub-word line drivers of FIG. 12.

In FIGS. 17a, 17b, and 17c, placements 711 and 715 respectively corresponding to the placements 311 and 315 of FIG. 13 are illustrated.

Photomasks MSKP11-1, MSKP11-2, and MSKP11-3 for manufacturing the placement 711 and photomasks MSKP15-1, MSKP15-2, MSKP15-3, and MSKP 15-4 for manufacturing the placement 715 are illustrated together in FIG. 17a. Photomasks MSKP21-1, MSKP21-2, MSKP21-3, MSKP21-4, and MSKP21-5 for manufacturing the placement 711 and photomasks MSKP25-1, MSKP25-2, MSKP25-3, MSKP25-4, and MSKP25-5 for manufacturing the placement 715 are illustrated together in FIG. 17b. Photomasks MSKP31-1 and MSKP31-2 for manufacturing the placement 711 and a photomask MSKP35-1 for manufacturing the placement 715 are illustrated together in FIG. 17c.

In an embodiment, the photomasks MSKP11-1, MSKP11-2, MSKP11-3, MSKP15-1, MSKP15-2, MSKP15-3, and MSKP15-4 of FIG. 17a may be for forming source regions of pull-down transistors of sub-word line drivers (e.g., SWD0, SWD2, SWD4, SWD6, SWD8, SWD10, SWD12, and SWD14 of FIG. 12).

In an embodiment, the photomasks MSKP21-1, MSKP21-2, MSKP21-3, MSKP21-4, MSKP21-5, MSKP25-1, MSKP25-2, MSKP25-3, MSKP25-4, and MSKP25-5 of FIG. 17b may be for forming drain regions of pull-down transistor and keeping transistors of the sub-word line drivers (e.g., SWD0, SWD2, SWD4, SWD6, SWD8, SWD10, SWD12, and SWD14 of FIG. 12).

In an embodiment, the photomasks MSKP31-1, MSKP31-2, and MSKP35-1 of FIG. 17c may be for forming the source regions of the pull-down transistors of the sub-word line drivers (e.g., SWD0, SWD2, SWD4, SWD6, SWD8, SWD10, SWD12, and SWD14 of FIG. 12).

Referring to FIGS. 17a, 17b, and 17c, the photomasks for manufacturing the placement 715 may be superior in performance to the photomasks for manufacturing the placement 711. For example, various patterns included in a sub-word line driver may be formed to be close in shape to ideal patterns according to the design rule or layout described with reference to FIG. 16.

In an embodiment, the performance of the photomasks may be evaluated based on photomask intervals including an average interval, a maximum interval, and a minimum interval between photomasks, a dispersion value and a standard deviation of the photomask intervals, and a height and a width of each of the photomasks.

In an embodiment, as the performance of the photomask is improved, various patterns included in the sub-word line driver may be elaborately formed. For example, various patterns included in the sub-word line driver may include the transistors, the doping regions, and the metal lines described with reference to FIGS. 7 to 12.

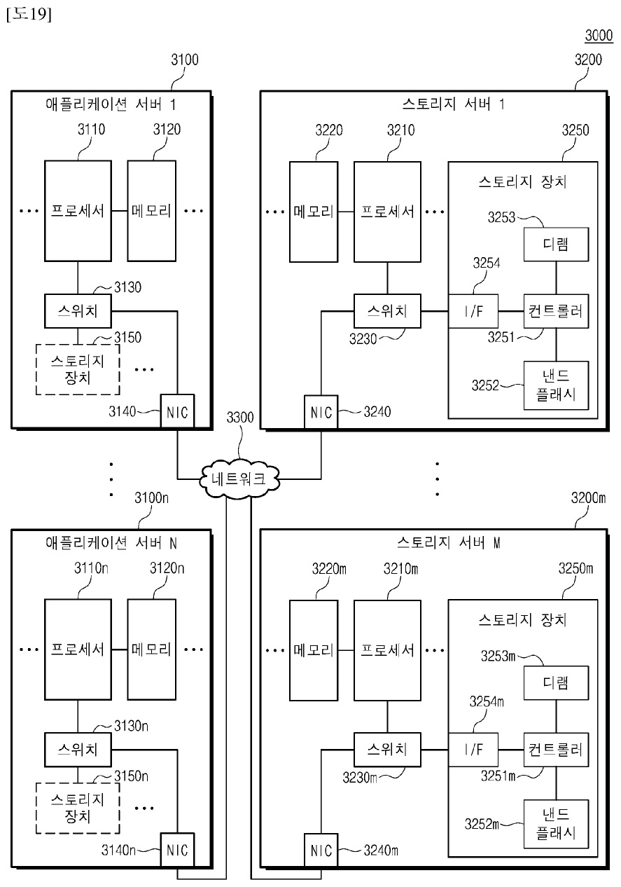

FIG. 18 is a block diagram illustrating a computing system including sub-word line drivers according to an embodiment of the present disclosure.

FIG. 18 is a block diagram illustrating a computing system including a semiconductor memory device according to embodiments of the present disclosure. Referring to FIG. 18, a computing system 1000 includes a processor 1100, an input/output hub 1200, an input/output controller hub 1300, at least one DRAM module 1400, and a graphics card 1500. Herein, the computing system 1000 may be any one of a PC (Personal Computer), a server computer, a workstation, a laptop, a mobile phone, a smart phone, a PDA (Personal Digital Assistant), a PMP (Portable Multimedia Player), a digital camera, a digital television, a set-top box, a music player, a portable game console, and a navigation system.

The processor 1100 may execute various computing functions such as specific calculations or tasks. For example, the processor 1100 may be a micro-processor or a central processing unit (CPU). The processor 1100 may include one processor core (i.e., a single core) or may include a plurality of processor cores (i.e., a multi-core). For example, the processor 1100 may include a multi-core such as a dual-core, a quad-core, or a hexa-core. Also, the computing system 1000 including one processor 1100 is illustrated in FIG. 18, but the computing system 1000 may include a plurality of processors. Also, the processor 1100 may further include a cache memory which is placed therein or on the outside.

The processor 1100 may include a memory controller 1150 which controls an operation of the DRAM module 1400. The memory controller 1150 included in the processor 1100 may be called an integrated memory controller (IMC). A memory interface between the memory controller 1150 and the DRAM module 1400 may be implemented with one channel including a plurality of signal lines or may be implemented with a plurality of channels. Also, one or more DRAM modules 1400 may be connected to each channel. The memory controller 1150 may be placed in the input/output hub 1200. The input/output hub 1520 including the memory controller 1150 may be called a memory controller hub (MCH).

The DRAM module 1400 may include a plurality of DRAM devices which store data provided from the memory controller 1150. Each of the DRAM devices may be implemented with the semiconductor memory device 500 of FIG. 15. That is, each of the DRAM devices may include a semiconductor memory device which reduces the chip size according to embodiments of the present disclosure and allows patterns included in a sub-word line driver to be formed elaborately.

The input/output hub 1200 may manage the data transmission between the processor 1100 and devices such as the graphics card 1500. The input/output hub 1200 may be connected to the processor 1510 through various manners of interfaces. For example, the input/output hub 1200 and the processor 1100 may be connected by various standards of interfaces such as FSB (Front Side Bus), system bus, HyperTransport, LDT (Lightning Data Transport), QPI (QuickPath Interconnect), and CSI (Common System Interface). The computing system 1000 including one input/output hub 1200 is illustrated in FIG. 10, but the computing system 1000 may include a plurality of input/output hubs.

The input/output hub 1200 may provide various interfaces with devices. For example, the input/output hub 1200 may provide an AGP (accelerated Graphics Port) interface, a PCle (Peripheral Component Interface-Express), a CSA (Communications Streaming Architecture) interface, etc.

The graphics card 1500 may be connected to the input/output hub 1200 through the APG or PCle. The graphics card 1500 may control a display device (not illustrated) for displaying an image. The graphics card 1500 may include an internal semiconductor memory device and an internal processor for image data processing. According to an embodiment, the input/output hub 1200 may include a graphics device in the input/output hub 1200 together with the graphics card 1500 placed outside the input/output hub 1200 or instead of the graphics card 1500. The graphics device included in the input/output hub 1520 may be called an integrated graphics. Also, the input/output hub 1200 including the memory controller and the graphics device may be called a graphics memory controller hub (GMCH).

The input/output controller hub 1300 may perform data buffering and interface arbitration such that various system interface efficiently operates. The input/output controller hub 1300 may be connected to the input/output hub 1200 through an internal bus. For example, the input/output hub 1200 and the input/output controller hub 1300 may be connected through a DMI (Direct Media Interface), a hub interface, an ESI (Enterprise Southbridge Interface), PCle, etc.

The input/output controller hub 1300 may provide various interfaces with peripheral devices. For example, the input/output controller hub 1300 may provide a universal serial bus (USB) port, a serial advanced technology attachment (SATA) port, a general purpose input/output (GPIO), a low pin count (LPC) bus, a serial peripheral interface (SPI), PCI, PCle, etc.

In an embodiment, the processor 1100, the input/output hub 1200, and the input/output controller hub 1300 may be implemented with separated chipsets or integrated circuits, or two or more components of the processor 1100, the input/output hub 1200, or the input/output controller hub 1300 may be implemented with one chipset.

FIG. 19 is a diagram illustrating a data center to which a semiconductor memory device including sub-word line drivers according to an embodiment of the present disclosure is applied.

Referring to FIG. 19, a data center 3000 which is a facility collecting various kinds of data and providing services may be referred to as a “data storage center”. The data center 3000 may be a system for operating a search engine and a database and may be a computing system used by companies, such as banks, or government agencies. The data center 3000 may include application servers 3100 to 3100n and storage servers 3200 to 3200m. The number of application servers 3100 to 3100n and the number of storage servers 3200 to 3200m may be variously selected according to embodiments, and the number of application servers 3100 to 3100n may be different from the number of storage servers 3200 to 3200m.

The application server 3100 or the storage server 3200 may include at least one of processors 3110 and 3210 and memories 3120 and 3220. The storage server 3200 will be described as an example. The processor 3210 may control all operations of the storage server 3200, may access the memory 3220, and may execute instructions and/or data loaded in the memory 3220. The memory 3220 may be implemented with a DDR SDRAM (Double Data Rate Synchronous DRAM), an HBM (High Bandwidth Memory), an HMC (Hybrid Memory Cube), a DIMM (Dual In-line Memory Module), an Optane DIMM, and/or an NVMDIMM (Non-Volatile DIMM). In some embodiments, the number of processors 3210 included in the storage server 3200 and the number of memories 3220 included in the storage server 3200 may be variously selected. In an embodiment, the processor 3210 and the memory 3220 may provide a processor-memory pair. In an embodiment, the number of processors 3210 may be different from the number of memories 3220. The processor 3210 may include a single-core processor or a multi-core processor. The above description of the storage server 3200 may be similarly applied to the application server 3100. According to an embodiment, the application server 3100 may not include a storage device 3150. The storage server 3200 may include at least one storage device 3250. The number of storage devices 3250 included in the storage server 3200 may be variously selected according to embodiments.

The application servers 3100 to 3100n may communicate with the storage servers 3200 to 3200m through a network 3300. The network 3300 may be implemented by using a fiber channel (FC) or Ethernet. In this case, the FC may be a medium used for relatively high-speed data transmission and may use an optical switch with high performance and high availability. The storage servers 3200 to 3200m may be provided as file storage, block storage, or object storage depending on an access method of the network 3300.

In an embodiment, the network 3300 may be a storage-dedicated network such as a storage area network (SAN). For example, the SAN may be an FC-SAN which uses an FC network and is implemented depending on an FC protocol (FCP). For another example, the SAN may be an IP-SAN which uses a TCP/IP network and is implemented depending on an iSCSI (SCSI over TCP/IP or Internet SCSI). In another embodiment, the network 3300 may be a general network such as a TCP/IP network. For example, the network 3300 may be implemented in compliance with a protocol such as FC over Ethernet (FCoE), network attached storage (NAS), and NVMe over Fabrics (NVMe-oF).

Below, the application server 3100 and the storage server 3200 will mainly be described. A description of the application server 3100 may be applied to another application server 3100n, and a description of the storage server 3200 may be applied to another storage server 3200m.

The application server 3100 may store data, which are requested by a user or a client to be stored, in one of the storage servers 3200 to 3200m through the network 3300. Also, the application server 3100 may obtain data, which are requested by the user or the client to be read, from one of the storage servers 3200 to 3200m through the network 3300. For example, the application server 3100 may be implemented as a web server or a database management system (DBMS).

The application server 3100 may access a memory 3120n or a storage device 3150n, which is included in another application server 3100n, through the network 3300; alternatively, the application server 3100 may access memories 3220 to 3220m or storage devices 3250 to 3250m, which are included in the storage servers 3200 to 3200m, through the network 3300. According to the above description, the application server 3100 may perform various operations on data stored in the application servers 3100 to 3100n and/or the storage servers 3200 to 3200m. For example, the application server 3100 may execute an instruction for moving or copying data between the application servers 3100 to 3100n and/or the storage servers 3200 to 3200m. In this case, the data may be moved from the storage devices 3250 to 3250m of the storage servers 3200 to 3200m to the memories 3120 to 3120n of the application servers 3100 to 3100n directly or through the memories 3220 to 3220m of the storage servers 3200 to 3200m. The data moved through the network 3300 may be data encrypted for security or privacy.

The storage server 3200 will be described as an example. An interface 3254 may provide a physical connection between the processor 3210 and a controller 3251 and a physical connection between an NIC 3240 and the controller 3251. For example, the interface 3254 may be implemented by using a direct attached storage (DAS) scheme in which the storage device 3250 is directly connected to a dedicated cable. Also, for example, the interface 3254 may be implemented in various interface manners such as ATA (Advanced Technology Attachment), SATA (Serial ATA), e-SATA (external SATA), SCSI (Small Computer Small Interface), SAS (Serial Attached SCSI), PCI (Peripheral Component Interconnection), PCle (PCI express), NVMe (NVM express), IEEE 1394, USB (Universal Serial Bus), an SD (Secure Digital) card, MMC (Multi-Media Card), eMMC (embedded Multi-Media Card), UFS (Universal Flash Storage), eUFS (embedded Universal Flash Storage), and/or CF (Compact Flash) card.

The storage server 3200 may further include a switch 3230 and the NIC 3240. Under control of the processor 3210, the switch 3230 may selectively connect the processor 3210 to the storage device 3250 or may selectively connect the NIC 3240 of the storage device 3250.

In an embodiment, the NIC 3240 may include a network interface card, a network adapter, etc. The NIC 3240 may be connected to the network 3300 by a wired interface, a wireless interface, a Bluetooth interface, or an optical interface. The NIC 3240 may include an internal memory, a digital signal processor (DSP), a host bus interface, etc. and may be connected to the processor 3210 and/or the switch 3230 through the host bus interface. The host bus interface may be implemented with one of the above examples of the interface 3254. In an embodiment, the NIC 3240 may be integrated with at least one of the processor 3210, the switch 3230, and the storage device 3250.

In the storage servers 3200 to 3200m or the application servers 3100 to 3100n, a processor may transmit a command to the storage devices 3150 to 3150n and 3250 to 3250m or the memories 3120 to 3120n and 3220 to 3220m and may program or read data. In this case, the data may be data whose error is corrected by an ECC engine. The data may be data on which a data bus inversion (DBI) operation or a data masking (DM) operation is performed and may include cyclic redundancy code (CRC) information. The data may be data encrypted for security or privacy.

The storage devices 3150 to 3150n and 3250 to 3250m may transmit a control signal and a command/address signal to NAND flash memory devices 3252 to 3252m in response to a read command received from the processor. In this case, when data are read from the NAND flash memory devices 3252 to 3252m, a read enable (RE) signal may be input as a data output control signal, and thus, the data may be output to a DQ bus. A data strobe DQS may be generated by using the RE signal. The command and the address signal may be latched in a page buffer depending on a rising edge or falling edge of a write enable (WE) signal.

The controller 3251 may control all operations of the storage device 3250. In an embodiment, the controller 3251 may include an SRAM. The controller 3251 may write data in the NAND flash 3252 in response to a write command or may read data from the NAND flash 3252 in response to a read command. For example, the write command and/or the read command may be provided from the processor 3210 of the storage server 3200, the processor 3210m of another storage server 3200 m, or the processors 3110 and 3110 n of the application servers 3100 and 3100n. A DRAM 3253 may temporarily store (or buffer) data to be written in the NAND flash 3252 or data read from the NAND flash 3252. Also, the DRAM 3253 may store meta data. Herein, the meta data are user data or data generated by the controller 3251 to manage the NAND flash 3252. The storage device 3250 may include an SE (Secure Element) for security or privacy.

The entire DRAM 3253 or a portion of the DRAM 3253 may include a semiconductor memory device according to embodiments of the present disclosure. Accordingly, each DRAM 3253 may include a semiconductor memory device which reduces the chip size according to embodiments of the present disclosure and allows patterns included in a sub-word line driver to be formed elaborately.

As described above, the semiconductor memory device according to embodiments of the present disclosure may reduce the chip size by reducing the area on a semiconductor substrate occupied by the sub-word line driver and may allow patterns included in sub-word line drivers to be formed elaborately by adjusting placements of transistors included in a sub-word line driver.

The above description refers to embodiments for implementing the present disclosure. In addition to the embodiments described above, the present disclosure may also include embodiments in which the design is simply changed or is easily changed. Also, technologies which are easily changed and implemented by using the above embodiments may be included in the present disclosure. Accordingly, the scope of the present disclosure should not be limited to the above embodiments and should be determined by those equivalent to the claims of the invention as well as the claims to be described below.

### INDUSTRIAL APPLICABILITY

Embodiments of the present disclosure may be usefully used in an arbitrary electronic device and system including a semiconductor memory device. For example, embodiments of the present disclosure may be more usefully applied to electronic systems such as a PC (Personal Computer), a server computer, a data center, a workstation, a laptop, a cellular, a smart phone, an MP3 player, a PDA (Personal Digital Assistant), a PMP (Portable Multimedia Player), a digital TV, a digital camera, a portable game console, a navigation system, a wearable device, an IoT (Internet of Things) device, an IoE (Internet of Everything) device, an e-book, an VR (Virtual Reality) device, an AR (Augmented Reality) device, and a drone.

1. A semiconductor memory device comprising:
a first sub-word line driver including a first pull-down transistor pulling down a first word line and a first keeping transistor maintaining a voltage level of the pulled-down first word line, in a deactivation interval of the first word line; and
a second sub-word line driver including a second pull-down transistor pulling down a second word line and a second keeping transistor maintaining a voltage level of the pulled-down second word line, in a deactivation interval of the second word line,
wherein a source region of the first pull-down transistor and a source region of the second keeping transistor are disposed to share a first doping region on a semiconductor substrate, and
wherein a source region of the second pull-down transistor and a source region of the first keeping transistor are disposed to share a second doping region on the semiconductor substrate.

2. The semiconductor memory device of claim 1, wherein a drain region of the first keeping transistor and a drain region of the first pull-down transistor are disposed to share a third doping region on the semiconductor substrate, and
wherein a drain region of the second keeping transistor and a drain region of the second pull-down transistor are disposed to share a fourth doping region on the semiconductor substrate.

3. The semiconductor memory device of claim 2, wherein the first to fourth doping regions are disposed on the semiconductor substrate to be spaced apart from each other and are disposed clockwise in order of the first doping region, the fourth doping region, the second doping region, and the third doping region with respect to a virtual center axis perpendicular to the semiconductor substrate.

4. The semiconductor memory device of claim 2, wherein the first doping region and the third doping region are disposed to form a point symmetry with the second doping region and the fourth doping region.

5. The semiconductor memory device of claim 1, wherein the first pull-down transistor and the first keeping transistor are disposed on the semiconductor substrate to form a point symmetry with the second pull-down transistor and the second keeping transistor.

6. The semiconductor memory device of claim 1, further comprising:
a first metal line electrically connected to gates of the first and second pull-down transistors;
a second metal line electrically connected to a gate of the first keeping transistor; and
a third metal line electrically connected to a gate of the second keeping transistor.

7. The semiconductor memory device of claim 6, wherein the first metal line extends in a first direction as much as a first length, then extends in a second direction different from the first direction as much as a second length, and again extends in the first direction as much as a third length.

8. The semiconductor memory device of claim 7,
wherein the first direction is a direction in which the first word line extends, and
wherein the second direction forms an angle of 45 degrees with the first direction.

9. The semiconductor memory device of claim 7, wherein the second metal line and the third metal line are disposed to be symmetrical with respect to the first metal line extending in the second direction.

10. The semiconductor memory device of claim 9, wherein the second metal line and the third metal line are disposed on a virtual line perpendicular to the second direction.

11. The semiconductor memory device of claim 7,
wherein the first metal line is configured to provides a first word line enable signal to the first and second pull-down transistors, and
wherein the second metal line and the third metal line are configured to provide first and second keeping control signals to the first and second keeping transistors, respectively.

12. The semiconductor memory device of claim 1, further comprising:
a first direct contact disposed on the first doping region; and
a second direct contact disposed on the second doping region,
wherein the first pull-down transistor and the second keeping transistor are configured to receive a negative voltage through the first direct contact, and
wherein the second pull-down transistor and the first keeping transistor are configured to receive the negative voltage through the second direct contact.

13. The semiconductor memory device of claim 1, wherein the first and second pull-down transistors and the first and second keeping transistors are a metal oxide semiconductor (MOS) transistor of a first conductivity.

14. The semiconductor memory device of claim 1, wherein the first word line and the second word line extend to one side of a memory cell array and are adjacent to each other.

15. A semiconductor memory device comprising:
a memory cell array including a plurality of memory cells connected to a plurality of word lines; and
a first sub-word line driver to a fourth sub-word line driver,
wherein the first to fourth sub-word line drivers respectively activate a first word line to a fourth word line, which extend to one side of the memory cell array and are adjacent to each other, from among the plurality of word lines,
wherein the first sub-word line driver includes:
a first pull-down transistor pulling down the first word line, in a deactivation interval of the first word line; and
a first keeping transistor maintaining a voltage level of the pulled-down first word line, in the deactivation interval of the first word line,
wherein the second sub-word line driver includes:
a second pull-down transistor pulling down the second word line, in a deactivation interval of the second word line; and
a second keeping transistor maintaining a voltage level of the pulled-down second word line, in the deactivation interval of the second word line,
wherein a source region of the first pull-down transistor and a source region of the second keeping transistor are disposed to share a first doping region on a semiconductor substrate, and
wherein a source region of the second pull-down transistor and a source region of the first keeping transistor are disposed to share a second doping region on the semiconductor substrate.

16. The semiconductor memory device of claim 15, wherein the third sub-word line driver includes:
a third pull-down transistor pulling down the third word line, in a deactivation interval of the third word line; and
a third keeping transistor maintaining a voltage level of the pulled-down third word line, in the deactivation interval of the third word line, and
wherein the fourth sub-word line driver includes:
a fourth pull-down transistor pulling down the fourth word line, in a deactivation interval of the fourth word line; and
a fourth keeping transistor maintaining a voltage level of the pulled-down fourth word line, in the deactivation interval of the fourth word line.

17. The semiconductor memory device of claim 16, further comprising:
a first metal line electrically connected to gates of the first to fourth pull-down transistors;
a second metal line electrically connected to a gate of the first keeping transistor;
a third metal line electrically connected to a gate of the second keeping transistor;
a fourth metal line electrically connected to a gate of the fourth keeping transistor; and
a fifth metal line electrically connected to a gate of the fourth keeping transistor.

18. The semiconductor memory device of claim 17,
wherein the first metal line extends in a first direction as much as a first length, then extends in a second direction different from the first direction as much as a second length, and again extends in the first direction as much as a third length,
wherein, after the first metal line extends in the first direction as much as the third length, the first metal line extends in a third direction different from the first direction as much as fourth length and again extends in the first direction as much as a fifth length.

19. The semiconductor memory device of claim 18,
wherein the first direction is a direction in which the first word line extends,
wherein the second direction forms an angle of 45 degrees with the first direction, and
wherein the third direction forms an angle of 45 degrees with the first direction and forms an angle of 90 degrees with the second direction.

20. A semiconductor memory device comprising:
a first sub-word line driver including a first pull-down transistor pulling down a first word line and a first keeping transistor maintaining a voltage level of the pulled-down first word line, in a deactivation interval of the first word line;
a second sub-word line driver including a second pull-down transistor pulling down a second word line and a second keeping transistor maintaining a voltage level of the pulled-down second word line, in a deactivation interval of the second word line;
a first metal line electrically connected to gates of the first and second pull-down transistors;
a second metal line electrically connected to a gate of the first keeping transistor; and
a third metal line electrically connected to a gate of the second keeping transistor,
wherein a source region of the first pull-down transistor and a source region of the second keeping transistor are disposed to share a first doping region on a semiconductor substrate,
wherein a source region of the second pull-down transistor and a source region of the first keeping transistor are disposed to share a second doping region on the semiconductor substrate,
wherein a drain region of the first keeping transistor and a drain region of the first pull-down transistor are disposed to share a third doping region on the semiconductor substrate, and
wherein a drain region of the second keeping transistor and a drain region of the second pull-down transistor are disposed to share a fourth doping region on the semiconductor substrate.
